(19) United States
(12) Patent Application Publication
(10) Pub. No.: US 2022/0246596 A1
(43) Pub. Date: Aug. 4, 2022

(54) Display Device

(71) Applicant: Semiconductor Energy Laboratory Co., Ltd., Kanagawa-ken (JP)

(72) Inventors: Shunpei YAMAZAKI, Setagaya, Tokyo (JP); Hideaki SHISHIDO, Atsugi,Kanagawa (JP); Koji KUSUNOKI, Isehara, Kanagawa (JP); Takahiro FUKUTOME, Atsugi, Kanagawa (JP)

(73) Assignee: Semiconductor Energy Laboratory Co., Ltd., Kanagawa-ken (JP)

(21) Appl. No.: 17/619,427

(22) PCT Filed: Jun. 12, 2020
(86) PCT No.: PCT/IB2020/055511

§ 371 Date: Dec. 15, 2021

(30) Foreign Application Priority Data
Jun. 28, 2019 (JP) 2019-121753

(51) Int. Cl. H01L 25/18; H01L 27/32; B81B 7/00

(52) U.S. Cl. CPC H01L 25/18; H01L 27/3276; H01L 24/16; H01L 2224/16145; B81B 7/0006

(57) ABSTRACT

A display device having a narrow bezel region is provided. The display device includes a first layer and a second layer. The first layer includes a source driver and one part of a sensor, and the second layer includes a gate driver, a plurality of pixels, and the other part of the sensor. The plurality of pixels include a pixel in which a light-emitting element emits light and a pixel having a function of the gate driver. An opening portion where the one part of the sensor is formed and a first terminal connected to the source driver are provided on the top surface of the first layer, and a second terminal is provided on the opposite side of the surface where the pixels included in the second layer are arranged. The first terminal is bonded to the second terminal, so that they are electrically connected to each other and the sensor is formed. Since an output signal of the source driver is directly supplied through the first terminal to a wiring to which the plurality of pixels are connected, the source driver and the gate driver do not need to be provided in a peripheral region of a display region where the plurality of pixels are provided.

### TECHNICAL FIELD

One embodiment of the present invention relates to a display device.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter.

In this specification and the like, a semiconductor device generally means a device that can function by utilizing semiconductor characteristics. Thus, a semiconductor element such as a transistor or a diode and a circuit including a semiconductor element are semiconductor devices. A display device, a light-emitting device, a lighting device, an electro-optical device, a communication device, an electronic device, and the like may include a semiconductor element or a semiconductor circuit. Therefore, a display device, a light-emitting device, a lighting device, an electro-optical device, an imaging device, a communication device, an electronic device, and the like are referred to as a semiconductor device in some cases.

### BACKGROUND ART

Wearable electronic devices that are easy to carry and are worn on a body to be used have been increasingly used. Typical examples of the wearable electronic devices include smartphones, smartwatches (registered trademark), tablet terminals, glasses-type displays, and goggle-type displays (head-mounted displays).

A wearable electronic device has been required to have a small housing, be lightweight, and have display performance with high resolution. For example, a goggle-type display can increase realistic sensation by displaying a large amount of information, and thus a display device with high resolution has been required. When the electronic device is small and lightweight, a load and fatigue on a body wearing the electronic device can be reduced.

The amount of data used in electronic devices tends to increase due to the development of information technology, such as IoT (Internet of Things) which connects electronic devices other than information terminals (e.g., in-vehicle electronic devices, home electronic appliances, houses, buildings, or wearable devices) to the Internet. In addition, the communication speed of electronic devices such as information terminals needs to be improved.

To achieve IoT, the number of electronic devices that are additionally connected to the Internet is increased; thus, the number of electronic devices that can be connected to the Internet at a time needs to be increased. Furthermore, since a large number of electronic devices are connected to the Internet at a time, a communication time lag (can be referred to as delay) occurs. Thus, in order to be compatible with various kinds of information technology including IoT, a new communication standard called the fifth-generation mobile communication system (5G) that achieves higher transmission speed, more simultaneous connections, and shorter delay time than 4G has been examined. For example, 5G uses communication frequencies of a 3.7 GHz band, a 4.5 GHz band, and a 28 GHz band.

Patent Document 1 discloses a display device in which a pixel includes part of a gate driver circuit so that a region where a gate driver is placed can be reduced.

### REFERENCE

### Patent Document

[Patent Document 1] PCT International Publication No. 2014-069529

### SUMMARY OF THE INVENTION

### Problems to be Solved by the Invention

Display devices with various shapes are used for wearable electronic devices depending on the purpose. Thus, there is a problem in that the electronic device has to be applicable to not only display devices with a shape surrounded by sides facing each other but also display devices with shapes other than the shape surrounded by sides facing each other, such as a circular shape, an elliptical shape, and a triangular shape. Moreover, in the case where the electronic device is worn for a long time and the electronic device is large and heavy, there is a problem in that a large load is put on a body and the degree of fatigue increases. Note that in the case where the electronic device has a large number of components, there is a problem in that the power consumption increases and the size of a housing of the electronic device increases.

An electronic device connected to a network using 5G involving IoT has been required to easy to carry and small. In the case where communication is performed using 5G, there is a problem in that antennas for transmission and reception using different frequency bands need to be provided.

An object of one embodiment of the present invention is to provide a display device or the like having a novel structure. Another object is to provide a display device or the like including a display region with a free shape. Another object is to provide a display device or the like having a structure suitable for miniaturization. Another object is to provide a display device or the like with high productivity.

Another object of one embodiment of the present invention is to provide an electronic device or the like having a novel structure. Another object is to provide an electronic device or the like including a display device including a display region whose shape is not limited to a shape surrounded by sides facing each other. Another object is to provide an electronic device or the like including a display device having a structure suitable for miniaturization. Another object is to provide an electronic device or the like including a display device with high productivity.

Note that the description of these objects does not preclude the existence of other objects. In one embodiment of the present invention, there is no need to achieve all the objects. Objects other than these are apparent from the description of the specification, the drawings, the claims, and the like, and objects other than these can be derived from the description of the specification, the drawings, the claims, and the like.

### Means for Solving the Problems

One embodiment of the present invention is a display device including a first layer and a second layer. The first layer includes a source driver and a first component of a sensor. The second layer includes a gate driver, a plurality of pixels, and a second component of the sensor. The pixel includes a light-emitting element. The sensor is formed in a region overlapping with the source driver. An opening portion and a first terminal are included in the first layer. The first component of the sensor is provided in the opening portion. The first terminal is electrically connected to the source driver. The pixels are provided on a first surface of the second layer, and a second terminal is provided on a second surface opposite to the first surface. The second terminal is electrically connected to the pixels. The first terminal is electrically connected to the second terminal, and an output signal of the source driver can be supplied through the first terminal to a wiring to which the plurality of pixels are connected. Thus, in the display device, the source driver and the gate driver do not need to be provided in a peripheral region of a display region where the plurality of pixels are provided. Note that the sensor is a MEMS (Micro Electro Mechanical Systems).

Another embodiment of the present invention is a display device including a first layer and a second layer. The first layer includes a source driver. The second layer includes a gate driver, a plurality of pixels, and an antenna. One or both of the gate driver and the pixels are formed in a position overlapping with the antenna. The first layer includes a first terminal and a third terminal. The first terminal is electrically connected to the source driver. The pixels are provided on a first surface of the second layer. A second terminal is provided on a second surface opposite to the first surface. The second terminal is electrically connected to the pixels. The first terminal is electrically connected to the second terminal. The third terminal is electrically connected to an end portion of the antenna. An output signal of the source driver can be supplied through the first terminal to a wiring to which the plurality of pixels are connected.

In each of the above-described structures, the second layer preferably has a larger area than the first layer, and the second layer preferably includes a region overlapping with the first layer.

A first pixel and a second pixel are included as the pixels. The first pixel and the second pixel each include a light-emitting element. The second pixel preferably further includes a component of the gate driver. Note that the light-emitting element preferably contains an organic substance. Alternatively, the light-emitting element is preferably an LED (light emitting diode) or a micro LED.

In each of the above-described structures, the first terminal is preferably electrically connected to the second terminal through a conductive bump.

Another embodiment of the present invention that is different from the above is a display device including a first layer and a second layer. The first layer includes a first transistor and a first component of a sensor. The second layer includes a second transistor, a light-emitting element, and a second component of the sensor. The sensor is provided in a region overlapping with the first transistor. An opening portion and a first terminal are provided in the first layer. The first component of the sensor is provided in the opening portion. The first terminal is electrically connected to the first transistor. The light-emitting element is provided on a first surface of the second layer. A second terminal of the second transistor is provided on a second surface opposite to the first surface. The first terminal is electrically connected to the second terminal.

In the above-described structure, a semiconductor layer of the second transistor preferably includes a metal oxide. The second transistor preferably includes a back gate.

### Effect of the Invention

One embodiment of the present invention can provide a display device or the like having a novel structure. Alternatively, a display device or the like including a display region whose shape is not limited to a shape surrounded by sides facing each other can be provided. Alternatively, a display device or the like having a structure suitable for miniaturization can be provided. Alternatively, a display device or the like with high productivity can be provided.

Alternatively, an electronic device or the like having a novel structure can be provided. Alternatively, an electronic device or the like including a display device including a display region whose shape is not limited to a shape surrounded by sides facing each other can be provided. Alternatively, an electronic device or the like including a display device having a structure suitable for miniaturization can be provided. Alternatively, an electronic device or the like including a display device with high productivity can be provided.

Note that the description of these effects does not preclude the existence of other effects. One embodiment of the present invention does not need to have all the effects. Effects other than these are apparent from the description of the specification, the drawings, the claims, and the like, and effects other than these can be derived from the description of the specification, the drawings, the claims, and the like.

### BRIEF DESCRIPTION OF THE DRAWINGS

FIG. 1 is a diagram illustrating an electronic device.

FIG. 2A to FIG. 2D are diagrams illustrating a display device.

FIG. 3 is a circuit diagram illustrating a display device.

FIG. 4A and FIG. 4B are diagrams illustrating a display device.

FIG. 5A and FIG. 5B are diagrams illustrating a display device.

FIG. 6A and FIG. 6B are diagrams illustrating a sensor.

FIG. 7 is a block diagram illustrating a gate driver.

FIG. 8A is a block diagram illustrating a gate driver. FIG. 8B is a circuit diagram illustrating a gate driver.

FIG. 9A to FIG. 9D are diagrams illustrating pixels.

FIG. 10A and FIG. 10B are diagrams illustrating a display device.

FIG. 11 is a diagram illustrating an antenna.

FIG. 12 is a diagram illustrating a structure example of a wireless transmission/reception device.

FIG. 13 is a diagram illustrating a structure example of a wireless transmission/reception device.

FIG. 14A and FIG. 14B are diagrams showing a structure example of a transistor.

FIG. 15A to FIG. 15C are diagrams showing a structure example of a transistor.

FIG. 16A to FIG. 16C are diagrams showing a structure example of a transistor.

FIG. 17A is a table showing classifications of crystal structures of IGZO. FIG. 17B is a diagram showing an XRD spectrum of a CAAC-IGZO film. FIG. 17C is an image showing nanobeam electron diffraction patterns of a CAAC-IGZO film.

FIG. 18A to FIG. 18D are diagrams showing examples of electronic devices.

FIG. 19A to FIG. 19D are diagrams showing examples of an electronic device.

FIG. 20A to FIG. 20F are diagrams showing examples of electronic devices.

### MODE FOR CARRYING OUT THE INVENTION

Embodiments are described in detail with reference to the drawings. However, the present invention is not limited to the following description, and it is readily appreciated by those skilled in the art that modes and details can be modified in various ways without departing from the spirit and the scope of the present invention. Thus, the present invention should not be construed as being limited to the description in the following embodiments. Note that in the structures of the invention described below, the same portions or portions having similar functions are denoted by the same reference numerals in different drawings, and description thereof is not repeated.

The position, size, range, and the like of each component illustrated in the drawings and the like do not represent the actual position, size, range, and the like in some cases to facilitate understanding of the invention. Therefore, the disclosed invention is not necessarily limited to the position, size, range, or the like disclosed in the drawings and the like. For example, in the actual manufacturing process, a resist mask or the like might be unintentionally reduced in size by treatment such as etching, which is not illustrated in some cases for easy understanding.

In a top view (also referred to as a “plan view”), a perspective view, or the like, some components might be omitted for easy understanding of the drawings.

In addition, in this specification and the like, the terms “electrode” and “wiring” do not functionally limit these components. For example, an “electrode” is used as part of a “wiring” in some cases, and vice versa. Furthermore, the term “electrode” or “wiring” also includes the case where a plurality of “electrodes” or “wirings” are formed in an integrated manner, for example.

In this specification and the like, the resistance value of a “resistor” is sometimes determined depending on the length of a wiring. Alternatively, the resistance value is sometimes determined by connection of a conductive layer used for a wiring to a conductive layer with resistivity different from that of the conductive layer. Alternatively, a resistance value is sometimes determined by impurity doping in a semiconductor layer.

In this specification and the like, a “terminal” in an electric circuit refers to a portion that inputs or outputs current or voltage or receives or transmits a signal. Accordingly, part of a wiring or an electrode functions as a terminal in some cases.

Note that the term “over”, “above”, “under”, or “below” in this specification and the like does not necessarily mean that a component is placed directly over and in contact with or directly under and in contact with another component. For example, the expression “electrode B over insulating layer A” does not necessarily mean that the electrode B is formed on and in direct contact with the insulating layer A, and does not exclude the case where another component is provided between the insulating layer A and the electrode B. For example, the expression “conductive layer D over conductive layer C” does not necessarily mean that the conductive layer D is formed on and in direct contact with the conductive layer C, and does not exclude the case where another component is provided between the conductive layer C and the conductive layer D. The term “above” or “below” does not exclude the case where a component is placed in an oblique direction.

Furthermore, functions of a source and a drain are interchanged with each other depending on operation conditions, for example, when a transistor of different polarity is employed or when the direction of current flow is changed in circuit operation; therefore, it is difficult to define which is the source or the drain. Thus, the terms “source” and “drain” can be interchanged with each other in this specification.

In this specification and the like, the expression “electrically connected” includes the case where components are directly connected to each other and the case where components are connected through an “object having any electric function”. There is no particular limitation on the “object having any electric function” as long as electric signals can be transmitted and received between components that are connected through the object. Thus, even when the expression “electrically connected” is used, there is a case where no physical connection is made and a wiring just extends in an actual circuit. Furthermore, the expression “directly connected” includes the case where wirings formed of different conductive layers are connected through a contact to function as one wiring.

In this specification and the like, “parallel” indicates a state where two straight lines are placed at an angle of greater than or equal to −10° and less than or equal to 10°, for example. Accordingly, the case where the angle is greater than or equal to −5° and less than or equal to 5° is also included. Furthermore, the terms “perpendicular” and “orthogonal” indicate a state where two straight lines are placed at an angle of greater than or equal to 800 and less than or equal to 100°, for example. Accordingly, the case where the angle is greater than or equal to 850 and less than or equal to 950 is also included.

In this specification and the like, the terms “identical”, “same”, “equal”, “uniform”, and the like used in describing calculation values and measurement values allow for a margin of error of ±20% unless otherwise specified.

A voltage refers to a potential difference between a given potential and a reference potential (e.g., a ground potential or a source potential) in many cases. Therefore, the terms “voltage” and “potential” can be replaced with each other in many cases. In this specification and the like, “voltage” and “potential” can be replaced with each other unless otherwise specified.

Note that a “semiconductor” has characteristics of an “insulator” when the conductivity is sufficiently low, for example. Thus, a “semiconductor” can be replaced with an “insulator”. In that case, a “semiconductor” and an “insulator” cannot be strictly distinguished from each other because a border therebetween is not clear. Accordingly, a “semiconductor” and an “insulator” in this specification can be replaced with each other in some cases.

Furthermore, a “semiconductor” has characteristics of a “conductor” when the conductivity is sufficiently high, for example. Thus, a “semiconductor” can be replaced with a “conductor”. In that case, a “semiconductor” and a “conductor” cannot be strictly distinguished from each other because a border therebetween is not clear. Accordingly, a “semiconductor” and a “conductor” in this specification can be replaced with each other in some cases.

Note that ordinal numbers such as “first” and “second” in this specification and the like are used in order to avoid confusion among components and do not denote the priority or the order such as the order of steps or the stacking order. A term without an ordinal number in this specification and the like might be provided with an ordinal number in the scope of claims in order to avoid confusion among components. Furthermore, a term with an ordinal number in this specification and the like might be provided with a different ordinal number in the scope of claims. Furthermore, even when a term is provided with an ordinal number in this specification and the like, the ordinal number might be omitted in the scope of claims and the like.

Note that in this specification and the like, an “on state” of a transistor refers to a state in which a source and a drain of the transistor are regarded as being electrically short-circuited (also referred to as a “conducting state”). Furthermore, an “off state” of a transistor refers to a state in which a source and a drain of the transistor are regarded as being electrically disconnected (also referred to as a “non-conducting state”).

In this specification and the like, in some cases, “on-state current” means a current that flows between a source and a drain when a transistor is in an on state. Furthermore, in some cases, “off-state current” means a current that flows between a source and a drain when a transistor is in an off state.

In this specification and the like, a high power supply voltage VDD (hereinafter, also simply referred to as “VDD”, “H voltage”, or “H”) is a power supply voltage higher than a low power supply voltage VSS (hereinafter, also simply referred to as “VSS”, “L voltage”, or “L”). Furthermore, VSS is a power supply voltage lower than VDD. A ground voltage (hereinafter, also simply referred to as “GND” or “GND voltage”) can be used as VDD or VSS. For example, in the case where VDD is a ground voltage, VSS is a voltage lower than the ground voltage, and in the case where VSS is a ground voltage, VDD is a voltage higher than the ground voltage.

In this specification and the like, a gate refers to part or the whole of a gate electrode and a gate wiring. A gate wiring refers to a wiring for electrically connecting at least one gate electrode of a transistor to another electrode or another wiring.

In this specification and the like, a source refers to part or the whole of a source region, a source electrode, and a source wiring. A source region refers to a region in a semiconductor layer, where the resistivity is lower than or equal to a given value. A source electrode refers to part of a conductive layer that is connected to a source region. A source wiring refers to a wiring for electrically connecting at least one source electrode of a transistor to another electrode or another wiring.

In this specification and the like, a drain refers to part or the whole of a drain region, a drain electrode, and a drain wiring. A drain region refers to a region in a semiconductor layer, where the resistivity is lower than or equal to a given value. A drain electrode refers to part of a conductive layer that is connected to a drain region. A drain wiring refers to a wiring for electrically connecting at least one drain electrode of a transistor to another electrode or another wiring.

In the drawings and the like, for easy understanding of the voltage of a wiring, an electrode, or the like, “H” representing an H voltage or “L” representing an L voltage is sometimes written near the wiring, the electrode, or the like. In addition, enclosed “H” or “L” is sometimes written near a wiring, an electrode, or the like whose voltage changes. Moreover, a symbol “x” is sometimes written on a transistor in an off state.

### Embodiment 1

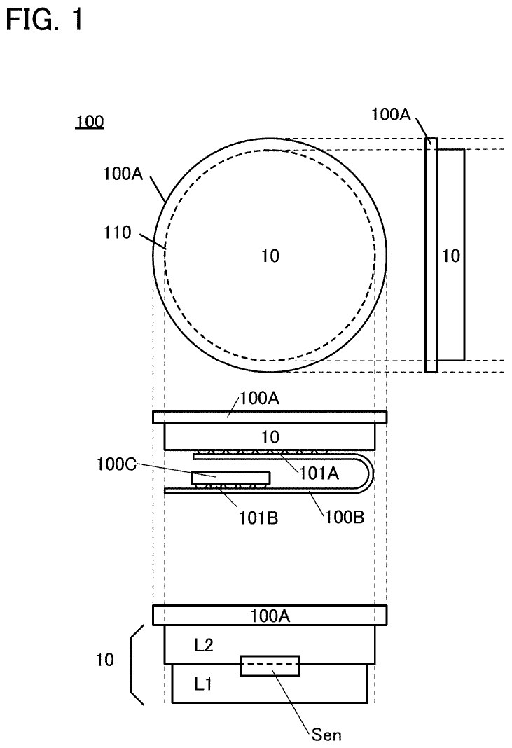

A display device of one embodiment of the present invention is described with reference to drawings. FIG. 1 is a diagram illustrating the structure of a display device 10 included in an electronic device 100.

Note that the structure of the display device shown in this specification and the like as an example is an example, and all of the components are not necessarily included. It is acceptable as long as the display device include necessary components among the components shown in this specification and the like. A component other than the components shown in this specification and the like may be included.

The electronic device 100 includes the display device 10, a substrate 100A, an FPC 100n, and a control device 100C as an example. The display device 10 is electrically connected to the FPC 100B through a bump 101A as an example. The FPC 100B is electrically connected to the control device 100C through a bump 101B. Thus, the display device 10 is electrically connected to the control device 100C through the FPC 100B.

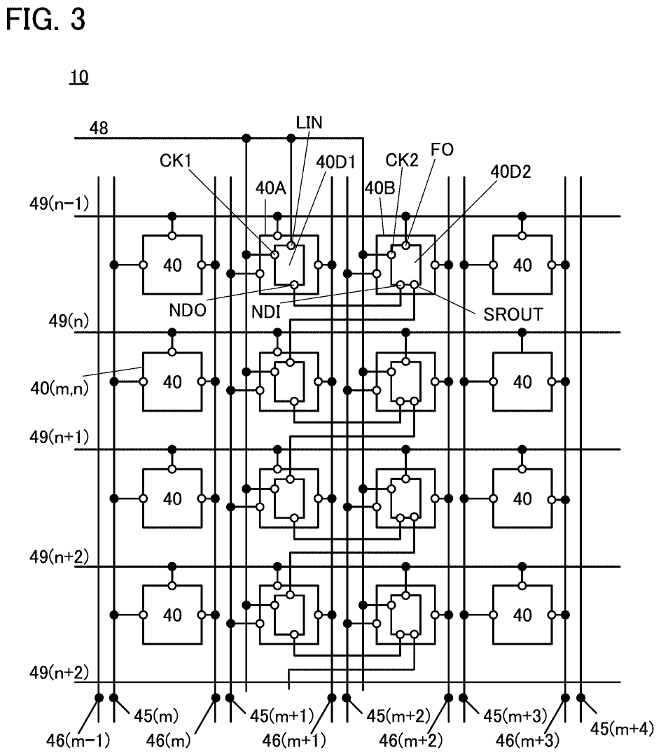

In one embodiment of the present invention, the display device 10 includes a layer L1 and a layer L2. The layer L1 includes a source driver and one part of a sensor Sen, and the layer L2 includes a gate driver, a plurality of pixels, and the other part of the sensor Sen. As the plurality of pixels, first pixels and second pixels are included. The first pixel and the second pixel each include a light-emitting element. The second pixel further has part of the function of the gate driver. The plurality of second pixels collectively achieve the function of the gate driver. In other words, the gate driver is formed of the plurality of second pixels. Note that the second pixel is described in detail with reference to FIG. 3. In addition, an opening portion where the one part of the sensor Sen is formed and a first terminal connected to the source driver are provided on a top surface of the layer L1, and a second terminal is provided on the rear side of a surface where the pixels included in the layer L2 are arranged.

The first terminal is bonded to the second terminal, so that they are electrically connected to each other and the sensor Sen is formed. Note that the first terminal may be electrically connected to the second terminal through a bump having conductivity (hereinafter, referred to as a bump). Directly bonding the first terminal to the second terminal through the bump is sometimes referred to as InFO (Integrated Fan-Out wafer level packaging) technology. Alternatively, it is possible to employ a direct bonding method in which the first terminal is directly bonded to the second terminal. In the case of employing the direct bonding method, the first terminal and the second terminal are preferably conductive films containing copper (Cu). Alternatively, the first terminal or the second terminal may be a conductive film containing tungsten (W).

An output signal of the source driver included in the layer L1 is supplied, through the first terminal and the second terminal, to a wiring to which the plurality of pixels are connected. That is, the source driver is provided under a display region where the plurality of pixels are provided. Therefore, the source driver or the gate driver does not need to be provided in a peripheral region of the display region. The display device of the electronic device can have a narrow bezel region, and thus the wide display region can be ensured. In the case where the source driver or the gate driver is not provided in the peripheral region of the display region, a region where the gate driver or the source driver is placed is not necessarily provided even for a display region with a shape surrounded by sides facing each other, a symmetrical shape formed of a straight line and a curved line, an asymmetrical shape formed of a straight line and a curved line, or a shape surrounded by sides not including sides facing each other (hereinafter, a free shape) such as a circular shape, an elliptical shape, or a triangular shape. In particular, the position of the FPC that supplies a signal to the source driver or the gate driver is not necessarily taken into consideration, so that a display device or electronic device including a display region with a free shape can be provided.

The area of the substrate 100A is preferably larger than that of the layer L2 and the area of the layer L2 is preferably larger than that of the layer L1. Note that the area of the substrate 100A may be the same as that of the layer L2. The area of the layer L2 may be the same as that of the layer L1. The substrate 100A is preferably placed in a position overlapping with the layer L2. The layer L2 is preferably placed in a position overlapping with the layer L1. Note that a display region 110 of the display device 10 is preferably a region having the same size as the layer L2 or a region smaller than the layer L2.

The light-emitting element included in the first pixel or the second pixel preferably contains an organic substance. A light-emitting element containing an organic substance can be referred to as an organic light-emitting element (OLED: Organic Light Emitting Device). Alternatively, the light-emitting element may contain an inorganic substance. Examples of a display element containing an inorganic substance include an LED (light emitting diode) and a micro LED.

The first terminal is electrically connected to the second terminal, so that the sensor Sen can be formed in a position not overlapping with the first terminal. As an example, the sensor Sen is preferably formed such that the one part of the sensor Sen is formed of a conductive layer containing the same element as the first terminal, and the other part of the sensor Sen is formed of a conductive layer containing the same element as the second terminal. Note that the sensor Sen is preferably a MEMS. As a different example, the sensor Sen can be formed using a conductive film containing an element different from an element contained in the first terminal or the second terminal.

As an example, the sensor Sen included in the display device 10 is preferably an acceleration sensor. Note that the sensor Sen is not limited to an acceleration sensor. For example, by changing the structure of the sensor Sen, a function of a pressure sensor, a gyroscope sensor, a bolometer-type infrared sensor, or the like can be given to the sensor Sen.

The substrate 100A has a function of protecting the display device. For example, glass, quartz, plastic, or the like can be used for the substrate 100A. Note that a flexible substrate may be used as the substrate 100A. The flexible substrate means a substrate that can be bent, such as a plastic substrate made of polycarbonate, polyarylate, or polyether sulfone, for example. A film made of polypropylene, polyester, polyvinyl fluoride, polyvinyl chloride, or the like, an inorganic film formed by evaporation, or the like can be used.

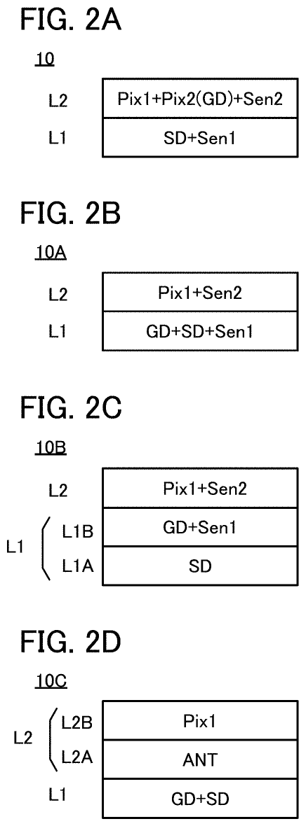

FIG. 2A to FIG. 2D are diagrams illustrating the display device 10. In FIG. 2A to FIG. 2D, the substrate 100A is not illustrated and description thereof is omitted for simplicity of description. The sizes of the layer L1 and the layer L2 are also not taken into consideration. The display device 10 includes one or more of a pixel Pix1, a pixel Pix2 (having a function of a gate driver GD), the gate driver GD, a source driver SD, the sensor Sen formed of a sensor Sen1 and a sensor Sen2, and an antenna ANT. When the display device 10 includes the pixel Pix2, the pixel Pix2 functions as the gate driver. When the display device 10 does not include the pixel Pix2, the gate driver GD preferably exists independently.

The layer L1 includes a first transistor and the layer L2 includes a second transistor. A first semiconductor layer included in the first transistor preferably contains an element different from that contained in a second semiconductor layer included in the second transistor. For example, the first semiconductor layer contains silicon (Si) and the second semiconductor layer contains oxygen and one or more of indium (In), zinc (Zn), gallium (Ga), and tin (Sn).

In other words, the second semiconductor layer includes an oxide semiconductor. Note that a transistor including an oxide semiconductor (OS), which is one kind of metal oxide, in a second semiconductor layer in which a channel of the transistor is formed is referred to as an “OS transistor” or “OS-FET”. Note that it is known that an OS transistor has a small change in electrical characteristics caused by temperature change. Furthermore, in an OS transistor, a semiconductor layer has a large energy gap, and thus the OS transistor can have an extremely low off-state current of several yA/μm (a current value per micrometer of a channel width). Therefore, an OS transistor is preferably used for a memory device. Note that the details of an OS transistor are described in Embodiment 3 or Embodiment 4.

The off-state current of an OS transistor hardly increases even in a high temperature environment. Specifically, the off-state current hardly increases even at an environment temperature higher than or equal to room temperature and lower than or equal to 200° C. In addition, the on-state current is unlikely to decrease even in high-temperature environments. An OS transistor has high withstand voltage between its source and drain. When OS transistors are used as transistors included in a semiconductor device, the semiconductor device achieves stable operation and high reliability even in a high-temperature environment.

An OS transistor can be formed by a sputtering method in a BEOL (Back end of line) process for forming a wiring of a semiconductor device. Thus, one display device 10 can be formed using transistors having different transistor characteristics. In other words, the use of an OS transistor facilitates formation of an SOC (System on chip).

FIG. 2A is a diagram illustrating, as an example, the structure of the display device 10 illustrated in FIG. 1. The layer L1 includes the source driver SD and the sensor Sen1. The layer L2 includes the pixel Pix1, the pixel Pix2, and the sensor Sen2. The sensor Sen2 is placed in a position overlapping with the sensor Sen1, whereby the sensor Sen is formed. Note that a light-emitting element included in the pixel Pix1 or the pixel Pix2 is preferably an OLED, an LED, or a micro LED.

Here, the display device 10 including a display region capable of high-resolution display will be described. For example, the display device 10 is preferably used for a head-mounted display.

The resolution of the pixel Pix formed in the layer L2 depends on the processing resolution of a manufacturing apparatus used in the manufacturing process of a transistor. For example, the gate length of a transistor that can be formed over a silicon substrate can be shorter than the shortest gate length of a transistor that can be formed over a glass substrate by greater than or equal to one digit. Therefore, the display region with high resolution is preferably formed over the silicon substrate.

As an example, the layer L2 including the pixel Pix1 and the pixel Pix2 having the function of the gate driver GD is formed by forming the pixels over a silicon substrate and then separating the silicon substrate. The separated silicon substrate can be used as a substrate when the layer L2 is formed again. Thus, the reuse of the substrate for forming the layer L2 can reduce the material cost.

Next, the layer L1 is preferably formed over a silicon substrate. The layer L1 includes at least the source driver SD. The source driver SD has a function of converting a digital signal into an analog signal and thus needs to operate at high speed. The plurality of pixels are connected to the wiring that is provided in the display region; the source driver SD is connected to the wiring. In other words, the wiring has a large capacity load to which parasitic capacitance is added. Thus, the source driver SD needs to have high current supply capability for charging and discharging the capacity load.

The source driver SD included in the layer L1 can achieve its function with a smaller area than the display region formed of the plurality of pixels included in the layer L2. For example, there is a problem in that when the layer L1 that has the same size and the same shape as the layer L2 including the display region with a free shape is processed as a chip, the number of chips obtained from one silicon substrate is small and the material cost increases. The area of the source driver SD included in the layer L1 is smaller than the area of the display region included in the layer L2 in many cases. Thus, by separately forming the layer L1 and the layer L2 and then bonding them to each other, the material cost can be reduced.

In the layer L1, the sensor Sen1 can be provided above the source driver SD. Furthermore, the sensor Sen2 included in the layer L2 is placed in a position overlapping with the sensor Sen1. By bonding the layer L1 and the layer L2 to each other, the sensor Sen is formed of the sensor Sen1 and the sensor Sen2. The sensor Sen is preferably a MEMS.

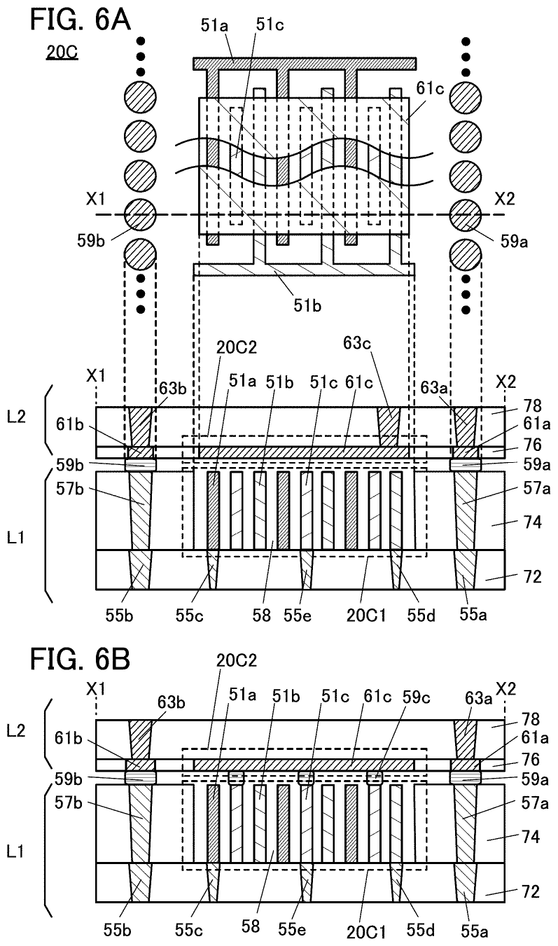

The sensor Sen will be described with reference to FIG. 6A and FIG. 6B in detail; here, the case where the sensor Sen1 includes first to third electrodes will be described as an example. The sensor Sen1 detects a change in a capacitor formed between the first electrode and the third electrode and a change in a capacitor formed between the second electrode and the third electrode. Note that part of the third electrode is preferably formed in the layer L2. When the sensor Sen2 is formed in the layer L2, the sensor Sen can detect not only operation or acceleration in the lateral direction but also operation, acceleration, or pressure such as pressing pressure in the longitudinal direction.

FIG. 2B is a diagram illustrating a display device 10A having a structure different from that of the display device 10 described with reference to in FIG. 2A. The display device 10A is different from the display device 10 in that the gate driver GD and the source driver SD are formed in the layer L1. Thus, the layer L2 includes a plurality of pixels Pix1, and the sensor Sen2 is provided on a surface opposite to the surface of the layer L2 where the pixels Pix1 are arranged. The first terminal is electrically connected to the second terminal, so that the sensor Sen is formed in a position not overlapping with the first terminal.

FIG. 2C is a diagram illustrating a display device 10B having a structure different from that of the display device 10A described with reference to FIG. 2B. The display device 10B is different from the display device 10A in that the layer L1 includes a layer L1A and a layer L1B. The display device 10B is different from the display device 10A in that the source driver SD is formed in the layer L1A and the gate driver GD and the sensor Sen1 are formed in the layer L1B. Note that the layer L1A includes the first transistor and the layer L1B includes the second transistor. Thus, the layer L1B is bonded to the layer L2, so that the first transistor and the second transistor form a stacked-layer structure.

FIG. 2D is a diagram illustrating a display device 10C having a structure different from that of the display device 10A described with reference to FIG. 2B. The display device 10C is different from the display device 10A in including the antenna ANT. Moreover, the display device 10C is different from the display device 10A in that the layer L2 includes a layer L2A and a layer L2B. The antenna ANT is formed in the layer L2A and the pixel Pix1 is formed in the layer L2B. The layer L2B includes the second transistor. Note that a plurality of antennas ANT are preferably formed in the layer L2A. The antennas ANT are electrically connected to a third terminal of the layer L1, and the third terminal preferably contains the same element as the first terminal.

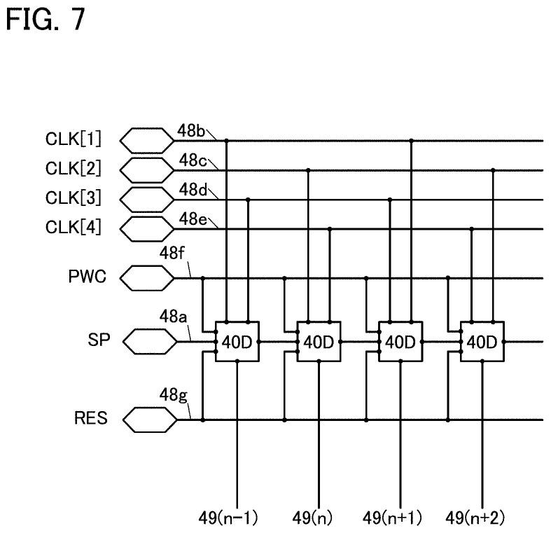

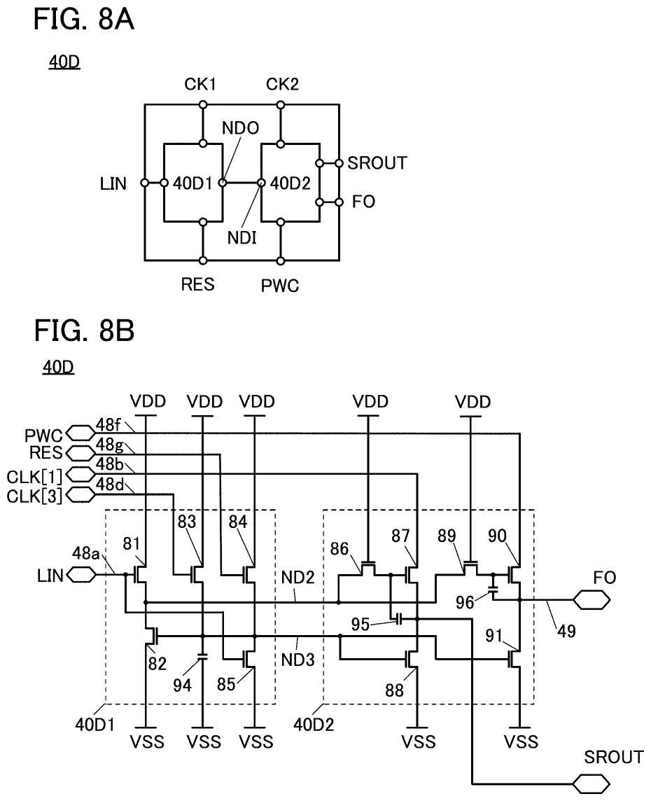

FIG. 3 is a circuit diagram specifically illustrating the layer L2 of the display device 10. The display device 10 includes a plurality of pixels 40, a plurality of pixels 40A, a plurality of pixels 40B, a plurality of wirings 45, a plurality of wirings 46, a wiring 48, and a plurality of wirings 49. Note that the pixel 40 corresponds to the pixel Pix1 described in the display device 10 and the function of the gate driver GD is preferably among the pixels Pix2. Thus, the pixel 40A and the pixel 40B each correspond to the pixel Pix2 described in the display device 10. Note that the gate driver GD will be described in detail with reference to FIG. 7, FIG. 8A, and FIG. 8B.

For example, each of the wirings 49 is electrically connected to the plurality of pixels 40, the plurality of pixels 40A, and the plurality of pixels 40B. The pixel 40A includes a circuit 40D1 having part of the function of the gate driver GD, and the pixel 40B includes a circuit 40D2 that is the rest of the function of the gate driver GD. Accordingly, the circuit 40D1 and the circuit 40D2, which are connected to the wiring 49, form a circuit corresponding to one stage of the gate driver GD. Although FIG. 3 shows an example in which the function of one stage of the gate driver GD is distributed and included in the two pixels, the number of pixels having the function of the gate driver GD is not limited. For example, the function of one stage of the gate driver GD can be distributed and included in three or more pixels.

First, the gate driver formed of the circuit 40D1 and the circuit 40D2 is described. The circuit 40D1 includes an input terminal LIN, an input terminal CK1, and an output terminal NDO, and the circuit 40D2 includes an input terminal CK2, an input terminal NDI, an output terminal FO, and an output terminal SROUT.

As an example, the wiring 48 is electrically connected to at least one of the input terminal LIN, the input terminal CK1, and the input terminal CK2. The output terminal NDO is electrically connected to the input terminal NDI. The output terminal FO is electrically connected to a wiring 49(n−1). The wiring 49(n−1) is electrically connected to the pixel 40, the pixel 40A, and the pixel 40B. The output terminal SROUT is electrically connected to the input terminal LIN of the circuit 40D1 included in the pixel 40A electrically connected to a wiring 49(n). Note that n is a positive integer.

Signals for driving the circuit 40D1 and the circuit 40D2 are supplied from the wiring 48 to the input terminal LIN, the input terminal CK1, and the input terminal CK2. A signal supplied to the output terminal NDO is an output signal of the circuit 40D1. The output signal is supplied to the input terminal NDI of the circuit 40D2. An output signal supplied to the output terminal FO corresponds to a scan signal in the display device. The output terminal SROUT is supplied with a carry signal for driving the circuit 40D1 included in the pixel 40A electrically connected to the wiring 49(n).

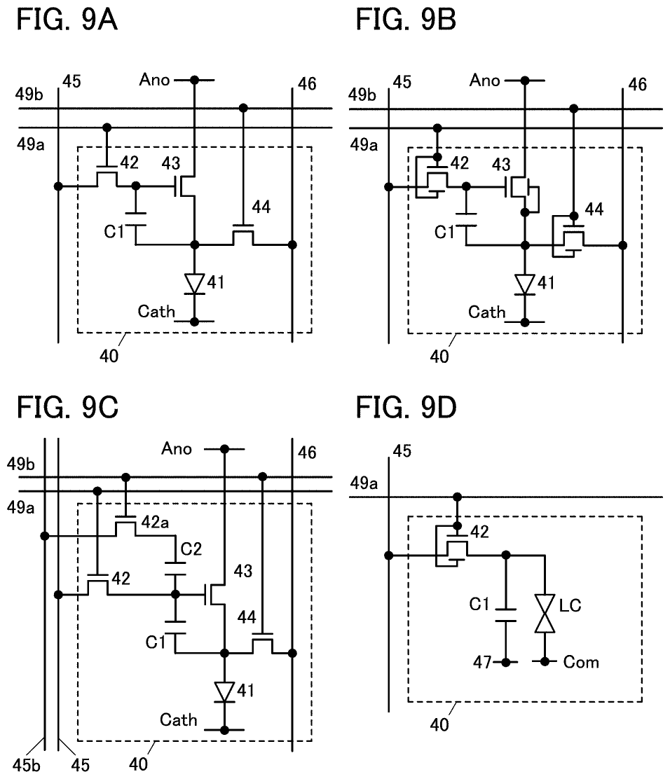

Next, the pixel 40, the pixel 40A, and the pixel 40B are described. The pixel 40, the pixel 40A, and the pixel 40B each include a light-emitting element and can control the intensity of light emitted from the light-emitting element. Note that the pixel 40 will be described in detail with reference to FIG. 9A to FIG. 9D.

Here, a pixel 40(m,n) is described as an example. The pixel 40(m,n) is electrically connected to a wiring 45(m), a wiring 46(m), and the wiring 49(n). To the wiring 45(m), image data is supplied from the source driver SD included in the layer L1 through the first terminal and the second terminal. To the wiring 46(m), a reset signal is supplied from the source driver SD included in the layer L1 through the first terminal and the second terminal. The pixel 40(m,n) can output to the wiring 46(m) a monitor signal for monitoring a change in the electrical characteristics of the pixel such as the amount of change in the threshold of the second transistor included in the pixel 40(m,n) or the amount of deterioration of the luminance of the light-emitting element. Note that m is a positive integer.

An output terminal of the source driver SD is electrically connected to the wiring 45 and the wiring 46 at any position in the display region. “In the display region” means a direction in which the pixels 40 electrically connected to the wiring 45 extend. “Outside the display region” means a direction in which the pixels 40 electrically connected to the wiring 45 do not exist.

Note that the source driver SD is preferably placed along a direction orthogonal to the plurality of wirings 45. Therefore, in the case where the source driver is electrically connected to the wiring 45 or the wiring 46 through the first terminal and the second terminal, they can be connected at the shortest distance.

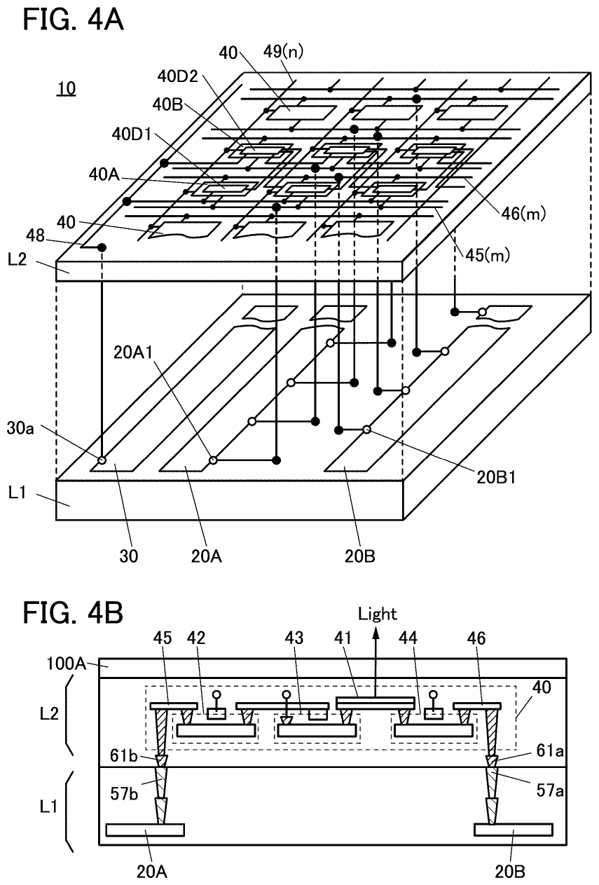

Furthermore, part of the wiring 48 may be led outside the display region. It is because control signals for driving the circuit 40D1 and the circuit 40D2 need to be supplied through the wiring 48 to the circuit 40D1 and the circuit 40D2 that are positioned at an end portion of the display region. Note that the control signals are supplied from a timing controller included in the layer L1. Note that the timing controller will be described in detail with reference to FIG. 4A.

FIG. 4A and FIG. 4B are diagrams illustrating the display device 10. FIG. 4A is a diagram for illustration using a perspective view of the display device 10, and FIG. 4B is a diagram for illustration using a schematic cross-sectional view of the display device 10. For the description of the layer L2, the description of FIG. 3 can be referred to. Thus, in the structures of the invention described below, the same portions or portions having similar functions are denoted by the same reference numerals in different drawings, and description thereof is not repeated.

In FIG. 4A, the layer L1 includes a source driver 20A and a source driver 20B that function as the source driver SD and a timing controller 30. The source driver 20A has a function of outputting image data. The source driver 20B has a function of outputting a reset signal, and the source driver 20B further has a monitoring function for monitoring a change in the electrical characteristics of the pixel 40.

As an example, an output terminal 20A1 of the source driver 20A is electrically connected to the wiring 45(m) in the display region through the first terminal and the second terminal. An output terminal 20B1 of the source driver 20B is electrically connected to the wiring 46(m) in the display region through the first terminal and the second terminal.

An output terminal 30a of the timing controller is electrically connected to the wiring 48 included in the layer L2 through the first terminal and the second terminal. One part of the wiring 48 is placed in the peripheral region of the display region, and another part of the wiring 48 is electrically connected to a plurality of circuits 40D1 and a plurality of circuits 40D2 in the display region.

FIG. 4B shows part of the schematic cross-sectional view of the display device 10. As an example, the layer L1 includes the source driver 20A and the source driver 20B and the layer L2 includes the pixel 40. Note that in FIG. 4B, the pixel 40A and the pixel 40B are not illustrated. In the pixel 40 illustrated in FIG. 4B, a light-emitting element 41, a transistor 42, a transistor 43, and a transistor 44 are illustrated as an example. Note that the light-emitting element 41 emits light in the direction of the substrate 100A. A pixel circuit of the pixel 40 will be described in detail with reference to FIG. 9A to FIG. 9D.

Note that the source driver 20A included in the layer L1 is electrically connected to the wiring 45 through a plug 57b and an electrode 61b. Moreover, it is shown that the source driver 20B is electrically connected to the wiring 46 through a plug 57a and an electrode 61a. Note that the plug 57a and the plug 57b correspond to the first terminal and the electrode 61a and the electrode 61b correspond to the second terminal.

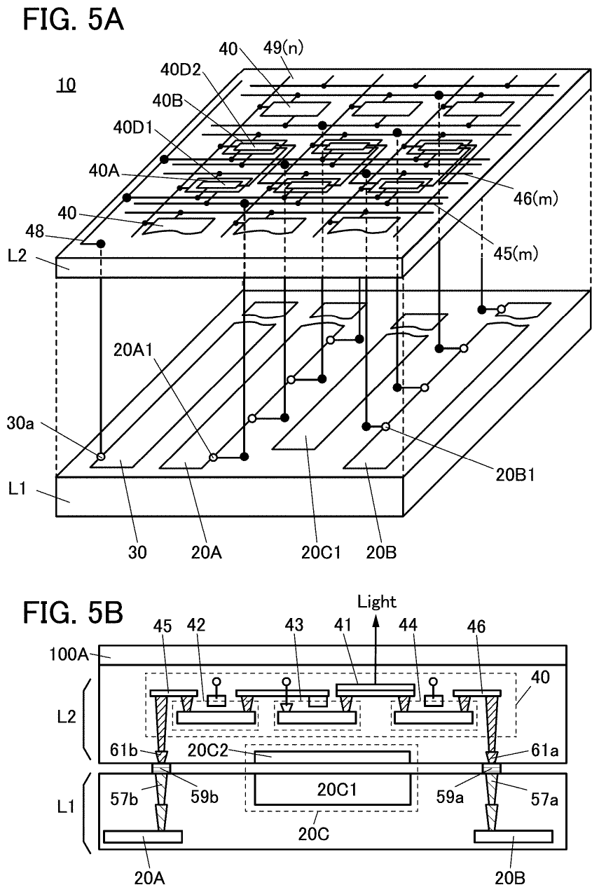

FIG. 5A and FIG. 5B are diagrams illustrating the display device 10 different from that in FIG. 4A and FIG. 4B. FIG. 5A is a diagram for illustration using a perspective view of the display device 10, and FIG. 5B is a diagram for illustration using a schematic cross-sectional view of the display device 10. For the description of the layer L2, the description of FIG. 4A and FIG. 4B can be referred to. Thus, in the structures of the invention described below, the same portions or portions having similar functions are denoted by the same reference numerals in different drawings, and description thereof is not repeated.

FIG. 5A is different from the display device 10 illustrated in FIG. 4A and FIG. 4B in that the display device 10 includes a sensor 20C. FIG. 5A illustrates that the layer L1 includes a sensor 20C1. The sensor 20C1 is placed in a position sandwiched between the source driver 20A and the source driver 20B. Note that there is no limitation on the position where the sensor 20C1 is placed.

FIG. 5B shows part of the schematic cross-sectional view of the display device 10. In the layer L1, the sensor 20C1, which is one of structure bodies of the sensor 20C, is provided, and in the layer L2, a sensor 20C2 is provided above the sensor 20C1. The sensor 20C is a MEMS that functions when the sensor 20C2 is placed above the sensor 20C1. The sensor 20C will be described in detail with reference to FIG. 6A and FIG. 6B.

Furthermore, FIG. 5B includes bumps 59 (a bump 59a and a bump 59b) for bonding the layer L1 and the layer L2. Since the layer L1 and the layer L2 are bonded to each other with the bumps 59, a space with the height of the bump 59 is formed between the sensor 20C1 of the layer L1 and the sensor 20C2 of the layer L2. The space forms a capacitance component between the sensor 20C1 and the sensor 20C2. Thus, the capacitance component is suitable for detecting acceleration or pressure from the same direction as the display direction of the display device.

FIG. 6A and FIG. 6B are diagrams specifically illustrating the sensor 20C described with reference to FIG. 5B. The sensor 20C is formed of an electrode 51a to an electrode 51c and an electrode 61c.

As an example, in the periphery of the sensor 20C, the bump 59a or the bump 59b for electrically connecting the source driver 20A or the source driver 20B included in the layer L1 to the wiring 45 and the wiring 46 included in the layer L2 is provided. Note that a plurality of bumps 59 are preferably used for electrically connecting the layer L1 to the layer L2.

FIG. 6A shows a schematic cross-sectional view of the sensor 20C along dashed-dotted line X1-X2. Note that since the schematic cross-sectional view mainly shows the sensor 20C, the source driver 20A and the source driver 20B included in the layer L1, the pixel 40 included in the layer L2, and the like are not illustrated because of paper space. Therefore, the description will be continued on the assumption that the source driver 20A and the source driver 20B are electrically connected below a plug 55a to a plug 55e and the pixel 40 is electrically connected above a plug 63a to a plug 63c.

First, the layer L1 is described. A plurality of conductive plugs 55a to 55d are formed in an insulating layer 72. An insulating layer 74 is formed over the insulating layer 72. The insulating layer 74 has an opening portion and includes the sensor 20C1 inside the opening portion. Note that when the opening portion where the sensor 20C1 is formed is formed, opening portions where the plug 57a and the plug 57b are formed are formed. Next, a conductive film is deposited, whereby the plug 57a and the plug 57b and the opening portions can be embedded in the conductive film.

Then, the conductive film is polished and planarized by a CMP (Chemical Mechanical Polishing) method until the insulating layer 74 is exposed. The conductive film formed in the opening portions is processed by a dry etching method, so that the electrode 51a to the electrode 51c are formed. Over the plug 57a and the plug 57b, the bump 59a and the bump 59b are formed. Note that the plug 55c to the plug 55e are electrically connected to the timing controller and the like formed in the layer L1. A detection circuit included in the timing controller detects a change in the capacitance value of capacitors (a first capacitor and a second capacitor) included in the sensor 20C1.

The electrode 51a to the electrode 51c are formed, whereby spaces 58 are formed in the sensor 20C1. The first capacitor is a capacitor generated by the space 58 sandwiched between the electrode 51a and the electrode 51c. The second capacitor is a capacitor generated by the space 58 sandwiched between the electrode 51b and the electrode 51c. A third capacitor is a capacitor generated by a space with the height of the bump 59a and the bump 59b, which is sandwiched between the electrode 51a to the electrode 51c and the electrode 61c. The third capacitor is suitable for detecting acceleration from a direction that is the same as or opposite to the direction in which light is emitted from the light-emitting element included in the display device. Note that the electrode 51a is electrically connected to the plug 55c. The electrode 51b is electrically connected to the plug 55d. The electrode 51c is electrically connected to the plug 55e. The electrode 61c is electrically connected to the plug 63c.

Next, the layer L2 will be described. In the layer L2, the electrode 61a, the electrode 61b, and the electrode 61c are exposed on the rear side of the surface where the pixel is placed. Note that the electrode 61a, the electrode 61b, and the electrode 61c are formed when embedded in an insulating film 76. An insulating film 78 is formed over the insulating film 76. The plug 63a and the plug 63b are formed in the insulating film 78. Note that the plug 63a is electrically connected to the electrode 61a. The plug 63b is electrically connected to the electrode 61b.

Note that the bump 59a and the bump 59b have a function of electrically connecting the layer L2 onto the layer L1. In other words, the bump 59a can electrically connect the plug 57a to the electrode 61a so that an output signal of the source driver SD or the like included in the layer L1 can be supplied to the pixel included in the layer L2. The bump 59b can electrically connect the plug 57b to the electrode 61b so that an output signal of the source driver SD or the like included in the layer L1 can be supplied to the pixel included in the layer L2.

FIG. 6B is a diagram illustrating a cross section of a sensor 20 different from that in FIG. 6A. In FIG. 6B, the electrode 61c is electrically connected to the electrode 51c through the bumps 59c. Note that the electrode 61c is preferably electrically connected to the electrode 51c through the plurality of bumps 59c. The electrode 61c is electrically connected to the electrode 51c, whereby distortion of the electrode 61c due to acceleration from a direction that is the same as or opposite to the direction in which light is emitted from the light-emitting element is transmitted to the electrode 51c, and a change due to the distortion of the electrode 51c is detected as a change in the capacitance values of the first to third capacitors. Thus, the display device 10 can detect acceleration from all directions to the display device 10 even when not provided with a plurality of acceleration sensors.

### <Structure Example of Gate Driver GD>

FIG. 7 is a block diagram in which only the circuit 40D1 and the circuit 40D2 that are discretely placed in the pixel 40A and the pixel 40B are extracted and illustrated. The gate driver GD includes a plurality of circuits 40D including n-channel transistors. The circuit 40D includes the circuit 40D1 and the circuit 40D2 illustrated in FIG. 3. The circuit 40D will be described in detail with reference to FIG. 8A and FIG. 8B.

To the gate driver GD, a signal SP is supplied through the wiring 48a, signals CLK[1] to CLK[4] are supplied through the wiring 48b to the wiring 48e, a signal PWC is supplied through the wiring 48f, and a signal RES is supplied through the wiring 48g. The signal SP is a start pulse signal. The signal RES is a reset signal; when the signal RES is set to a high potential, for example, all the outputs of the circuits 40D can be a low potential. The signal PWC is a pulse width control signal. The pulse width control signal has a function of controlling the pulse width of a signal output from the circuit 40D to the wiring 49. The signal CLK[1], the signal CLK[2], the signal CLK[3], and the signal CLK[4] are clock signals. For example, two of the signal CLK[1] to the signal CLK[4] are supplied to the circuit 40D.

For example, the structure illustrated in FIG. 7 can also be applied to the source driver SD by electrically connecting the circuit 40D to a different wiring.

FIG. 8A is a diagram illustrating the circuit 40D. The circuit 40D includes the circuit 40D1 and the circuit 40D2. The circuit 40D includes the input terminal LIN, the input terminal CK1, the input terminal CK2, an input terminal PWC, an input terminal RES, the output terminal FO, and the output terminal SROUT.

To the circuit 40D1, the signal SP is supplied through the input terminal LIN or a carry signal is supplied through the output terminal SROUT included in the circuit 40D2 in the previous stage. A clock signal is supplied to the circuit 40D1 through the input terminal CK1. A reset signal is supplied to the circuit 40D1 through the input terminal RES. The circuit 40D1 includes the output terminal NDO, and outputs to the output terminal NDO an intermediate signal generated by the circuit 40D1.

The circuit 40D2 includes the input terminal NDI and supplies to the input terminal NDI an intermediate signal generated by the circuit 40D1. A clock signal is supplied to the circuit 40D2 through the input terminal CK2. A pulse width control signal is supplied to the circuit 40D2 through the input terminal PWC. The circuit 40D2 supplies a carry signal to the input terminal LIN included in the circuit 40D1 in the next stage through the output terminal SROUT. The circuit 40D2 supplies a scan signal to the wiring 49 through the output terminal FO.

FIG. 8B is a circuit diagram illustrating the details of the circuit 40D. The circuit 40D includes a transistor 81 to a transistor 91 and a capacitor 94 to a capacitor 96.

One of a source and a drain of the transistor 81 is electrically connected to one of a source and a drain of the transistor 82, one of a source and a drain of the transistor 86, and one of a source and a drain of the transistor 89. A gate of the transistor 82 is electrically connected to one of a source and a drain of the transistor 83, one of a source and a drain of the transistor 84, one of a source and a drain of the transistor 85, a gate of the transistor 88, a gate of the transistor 91, and one electrode of the capacitor 94. The other of the source and the drain of the transistor 86 is electrically connected to a gate of the transistor 87 and one electrode of a capacitor 95. The other of the source and the drain of the transistor 89 is electrically connected to a gate of the transistor 90 and one electrode of the capacitor 96. One of a source and a drain of the transistor 90 is electrically connected to the wiring 49 through one of a source and a drain of the transistor 91, the other of the capacitor 96, and the output terminal FO.

A signal LIN is input to a gate of the transistor 81 and a gate of the transistor 85. The signal CLK[3] is input to a gate of the transistor 83. The signal RES is input to a gate of the transistor 84. The signal CLK[1] is input to one of a source and a drain of the transistor 87. The signal PWC is input to the other of the source and the drain of the transistor 90. A signal SROUT is output from the other of the source and the drain of the transistor 87, one of a source and a drain of the transistor 88, and the other electrode of the capacitor 95.

A potential VDD is supplied to the other of the source and the drain of the transistor 81, the other of the source and the drain of the transistor 83, the other of the source and the drain of the transistor 84, a gate of the transistor 86, and a gate of the transistor 89. A potential VSS is supplied to the other of the source and the drain of the transistor 82, the other of the source and the drain of the transistor 85, the other of the source and the drain of the transistor 88, the other of the source and the drain of the transistor 91, and the other electrode of the capacitor 94.

The circuit 40D1 includes the transistor 81 to the transistor 85 and the capacitor 94. The circuit 40D2 includes the transistor 86 to the transistor 91, the capacitor 95, and the capacitor 96. A wiring to which the one of the source and the drain of the transistor 81 and the one of the source and the drain of the transistor 86 are electrically connected is referred to as a node ND2 for explanation. A wiring to which the gate of the transistor 82 and the gate of the transistor 88 are electrically connected is referred to as a node ND3 for explanation.

The input terminal NDI is electrically connected to the output terminal NDO through the node ND2 and the node ND3. Note that FIG. 8B shows an example in which the signal CLK[3] is supplied to the input terminal CK1 and the signal CLK[1] is supplied to the input terminal CK2.

### <Structure Example of Pixel Pix>

FIG. 9A to FIG. 9D are circuit diagrams illustrating the pixel 40 in detail.

The pixel 40 in FIG. 9A includes the light-emitting element 41, the transistor 42 to the transistor 44, and a capacitor C1. One electrode of the light-emitting element 41 is electrically connected to one of a source and a drain of the transistor 43, one of a source and a drain of the transistor 44, and one electrode of the capacitor C1. A gate of the transistor 43 is electrically connected to the other electrode of the capacitor C1 and one of a source and a drain of the transistor 42. The other of the source and the drain of the transistor 42 is electrically connected to the wiring 45. Agate of the transistor 42 is electrically connected to a wiring 49a. The other of the source and the drain of the transistor 43 is electrically connected to a wiring Ano. A gate of the transistor 44 is electrically connected to a wiring 49b. The other of the source and the drain of the transistor 44 is electrically connected to the wiring 46. The other electrode of the light-emitting element 41 is electrically connected to a wiring Cath.

The transistor 42 to the transistor 44 are preferably OS transistors. Note that the transistor 42 to the transistor 44 are not limited to OS transistors. As an example, silicon can be used for a semiconductor layer. For example, amorphous silicon, polycrystalline silicon, low temperature poly-silicon (LTPS), or single crystal silicon can be used.

FIG. 9B is different from FIG. 9A in the transistor included in the pixel 40. As an example, the transistor 42 to the transistor 44 each have a back gate. The back gate is placed so that a channel formation region of the second semiconductor layer is sandwiched between the gate and the back gate. The back gate can function in a manner similar to that of the gate. By changing the voltage of the back gate, the threshold voltage of the transistor can be changed. The voltage of the back gate may be the same as that of the gate or may be a GND voltage or a given voltage.

In addition, in general, the gate and the back gate are formed using conductive layers and thus each have a function of preventing an electric field generated outside the transistor from influencing the semiconductor layer in which a channel is formed (particularly, a function of preventing static electricity). That is, variation in the electrical characteristics of the transistor due to the influence of an external electric field such as static electricity can be prevented.

FIG. 9C is a diagram illustrating the pixel 40 different from that in FIG. 9A. The pixel 40 in FIG. 9C is different from that in FIG. 9A in further including a transistor 42a and a capacitor C2. Note that in the following description of the structures of the invention, the same portions as those in FIG. 9A or portions having functions similar to those in FIG. 9A are denoted by the same reference numerals, and description thereof is not repeated.

Agate of the transistor 42a is electrically connected to the wiring 49b. One of a source and a drain of the transistor 42a is electrically connected to the wiring 45b. The other of the source and the drain of the transistor 42a is electrically connected to one electrode of the capacitor C2. The other electrode of the capacitor C2 is electrically connected to the gate of the transistor 43.

A voltage supplied to the gate of the transistor 43 depends on capacitive coupling of a voltage supplied to the capacitor C1 and a voltage supplied to the capacitor C2. Therefore, a voltage value larger than the maximum output voltage of the source driver can be supplied to the pixel as pixel data.

The pixel 40 illustrated in FIG. 9C can perform arithmetic processing of first image data to be supplied to the capacitor C1 and second image data to be supplied to the capacitor C2 by capacitive coupling, whereby third image data can be generated. This can be achieved by using an OS transistor characterized by a small off-state current, as a selection switch. As indicated by the pixel 40, a technology in which a pixel has an arithmetic function can be referred to as Pixel AI technology.

FIG. 9D is a diagram illustrating the pixel 40 including a liquid crystal element. FIG. 9D includes the transistor 42, the capacitor C1, and a liquid crystal element LC. The gate of the transistor 42 is electrically connected to the wiring 49a. The one of the source and the drain of the transistor 42 is electrically connected to the wiring 45. The other of the source and the drain of the transistor 42 is electrically connected to the one electrode of the capacitor C1 and one electrode of the liquid crystal element LC. The other electrode of the capacitor C1 is electrically connected to a wiring 47. The other electrode of the liquid crystal element LC is electrically connected to a wiring Com. Note that the other electrode of the capacitor C1 may be electrically connected to the wiring Com.

For the pixel 40 in FIG. 9D, the Pixel AI technology can be employed. For example, the Pixel AI technology can be employed by providing the transistor 42a and the capacitor C2 for the pixel 40 in FIG. 9D.

For example, in the case of a display device included in a wearable electronic device such as a head-mounted display, a display device that is small, lightweight, or capable of displaying a high-resolution image is needed. In addition, when the position or direction of a head wearing a head-mounted display is changed, displayed information also needs to be changed following the change. Thus, when the display device 10 is provided with an acceleration sensor, the conformity of display contents to the change is improved as compared to the case where display data is updated by information detected by an acceleration sensor placed at a different position.

Thus, when the layer L1 including the source driver and the like is bonded under the layer L2 including the display region with a free shape, a display device or the like with a free shape can be provided. Alternatively, when the display device 10 includes an acceleration sensor, a display device or the like having a novel structure can be provided. Alternatively, a display device or the like which has high productivity by including a MEMS as a component can be provided. As described above, since the display device 10 includes the pixel, the gate driver, the source driver, and the MEMS as components, the number of components used for an electronic device can be reduced. Furthermore, to the pixel utilizing capacitive coupling, a voltage higher than the maximum output voltage of the source driver can be supplied as image data. Accordingly, the power consumption of an electronic device including the display device 10 can be reduced.

The composition, structure, method, and the like described in this embodiment can be used in an appropriate combination with the compositions, structures, methods, and the like described in the other embodiments and the like.

### Embodiment 2

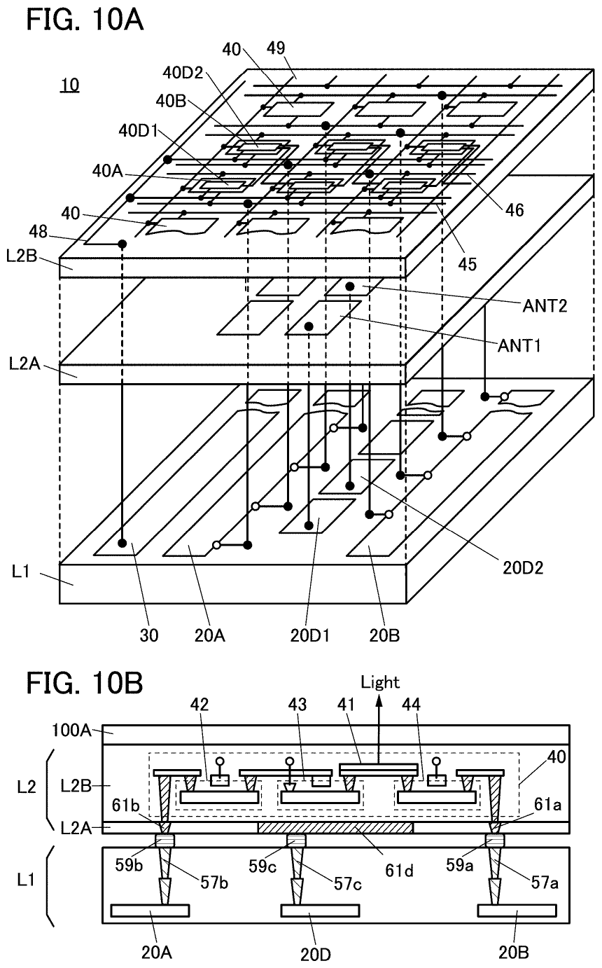

A display device of one embodiment of the present invention is described with reference to drawings. FIG. 10A and FIG. 10B are diagrams illustrating the structure of the display device 10 that is different from the structure in Embodiment 1. Note that in the structures of the invention described below, the same portions as Embodiment 1 or portions having functions similar to those in Embodiment 1 are denoted by the same reference numerals in different drawings, and description thereof is not repeated.

The display device 10 illustrated in FIG. 10A is different from that in FIG. 5A in that the layer L1 further includes a plurality of transmission/reception devices and the layer L2A includes a plurality of antenna regions. Note that in the antenna region of the layer L2A, the electrode 61a and the electrode 61b are preferably exposed on the rear side of the surface where the pixel is placed. A plurality of antennas are provided in the antenna region.

As an example, the antenna region includes a plurality of antenna regions ANT1 and a plurality of antenna regions ANT2. A frequency band of transmission and reception by the antenna region ANT1 is the same as or different from a frequency band of transmission and reception by the antenna region ANT2.

For example, the antenna included in the antenna region ANT1 and a transmission/reception device 20D1 are preferably placed at overlapping positions. The antenna included in the antenna region ANT1 is preferably electrically connected to an amplifier circuit included in the transmission/reception device 20D1 at the shortest distance. In addition, the antenna included in the antenna region ANT2 is preferably electrically connected to an amplifier circuit included in the transmission/reception device 20D2 at the shortest distance.

For example, the length of a wiring connecting the antenna and the amplifier circuit is preferably equal to the length of a wiring connecting another antenna and an amplifier circuit electrically connected to the antenna. The lengths of the wirings electrically connecting the antennas and the amplifier circuits are equal to each other, whereby variation in transmitted and received signals that depends on the lengths of the wirings can be suppressed.

As another example, when the lengths of the wirings electrically connecting the antennas and the amplifier circuits are made different from each other intentionally, a frequency band of reception can be widened. Since the wirings having different lengths have different impedance components, the wirings can function as part of a filter.

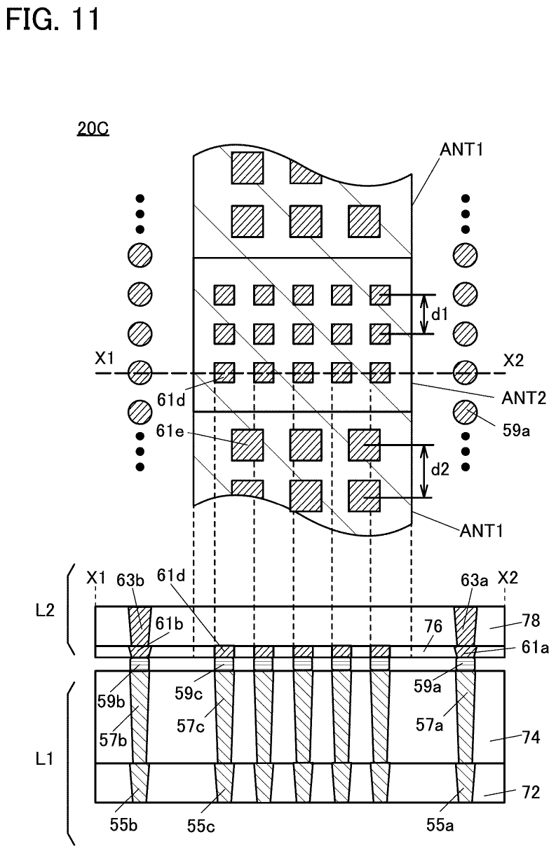

FIG. 10B shows part of a schematic cross-sectional view of the display device 10. FIG. 10B is different from FIG. 5B in that the transmission/reception device 20D is provided in the layer L1 and an electrode 61d functioning as an antenna is provided in the layer L2A. The electrode 61d will be described in detail with reference to FIG. 11.

Furthermore, the bumps 59 (the bumps 59a, 59b, and 59c) are provided between the layer L1 and the layer L2A in order to bond them to each other. The electrode 61d is electrically connected to a plug 57c through the bump 59c. The plug 57c is electrically connected to the transmission/reception device 20D. The layer L1 and the layer L2A are bonded to each other with the bumps 59, whereby a space with the height of the bump 59 is formed between the layer L1 and the layer L2. The space has an effect of reducing the contact area of an insulating film in contact with the electrode 61d. The insulating film in contact with the electrode 61d functioning as an antenna functions as a relative dielectric in transmission and reception through the antenna. In other words, as a larger number of relative dielectrics are in contact with the electrode 61d, a capacitive impedance is added in proportion to this. Thus, in designing the electrode 61d, the electrode 61d is preferably designed in consideration of a target frequency and the relative permittivity of the insulating film.

Although FIG. 10B shows an example in which the layer L1 is electrically connected to the layer L2A and the layer L2B through the bumps 59, the layer L1 can be directly bonded to the layer L2A and the layer L2B without through the bumps 59 in another example. As an example, the plug 57a included in the layer L1 and the electrode 61a included in the layer L2A and the layer L2B are preferably conductive films containing copper (Cu). Alternatively, either the plug 57a or the electrode 61a may be tungsten (W).

FIG. 11 is a diagram illustrating the details of the antenna illustrated in FIG. 10B. The upper part of FIG. 11 is a top view mainly illustrating the antenna region ANT1 and the antenna region ANT2. Here, the electrodes 61d functioning as the plurality of antennas provided in the antenna region ANT2 are described.

In communication using 5G, for example, the communication can be performed using a plurality of frequency bands such as 3.7 GHz, 4.5 GHz, and 28 GHz. The case where the electrode 61d, which is included in the antenna region ANT2 and functions as the antenna, performs communication using 28 GHz will be described as an example.

Note that the case where the electrode 61d included in the antenna region ANT2 is formed of a patch antenna (a microstrip antenna or a microstrip patch antenna) is described. A patch antenna is formed by arranging a plurality of processed square conductive films in an array. A distance d between the electrodes 61d is determined by a frequency band of transmission and reception. For example, in the case where the frequency band is 28 GHz, a distance d1 is approximately 5 mm. This can be calculated by Formula 1 below.

$$Distance d [ m ] = ( Speed of light [ m \text{/} s ] / Frequency band [ {s}^{- 1} ] / 2 \qquad ( 1 )$$

The length of one side of the electrode 61d functioning as an antenna is affected by the relative permittivity of the insulating film in contact with the antenna. For example, the length of one side of the electrode 61d can be calculated by Formula 2.

$$Length of one side [ m ] = Distance d [ m ] / √ Relative permittivity \qquad ( 2 )$$

In the case where the relative permittivity of a silicon dioxide film, which is a typical insulating film, is 3.9, the length of one side of the electrode 61d is approximately 2.5 mm. Note that the distance d and the length of one side are preferably changed as appropriate depending on the frequency band of transmission and reception and the relative permittivity in contact with the antenna. For example, the antenna region ANT1 includes electrodes 61e functioning as a plurality of antennas. As shown in FIG. 11, a distance d2 between the electrodes 61e is larger than the distance d1. In other words, it means that the frequency band of transmission and reception by the electrode 61e included in the antenna region ANT1 is narrower than at least 28 GHz.

That is, the antenna regions that perform transmission and reception using different frequency bands are arranged at adjacent positions or alternately arranged, whereby transmission and reception can be performed using different frequency bands. In communication using 5G, frequency bands to be used are sometimes switched depending on the situation an electronic device is in. For example, antenna regions that perform transmission and reception using different frequency bands are alternately arranged so that only the antenna region corresponding to a target frequency band transmits/receives a signal and the antenna region corresponding to a frequency band that is not a target does not operate; thus, the SN ratio is improved.

The lower part of FIG. 11 is a diagram illustrating a schematic cross-sectional view of the electrode 61d along dashed-dotted line X1-X2 in the top view. Note that since the schematic cross-sectional view mainly shows the electrode 61d, the source driver 20A, the source driver 20B, and the transmission/reception device 20D included in the layer L1, the pixel 40 included in the layer L2, and the like are not illustrated because of paper space. Therefore, the source driver 20A, the source driver 20B, and the transmission/reception device 20D are electrically connected below the plug 55a to the plug 55c and the pixel 40 is electrically connected above the plug 63a and the plug 63b. As illustrated in the lower part of FIG. 11, the electrode 61d is preferably electrically connected to the transmission/reception device 20D at the shortest distance through the bump 59c, the plug 57c, and the plug 55c in this order.

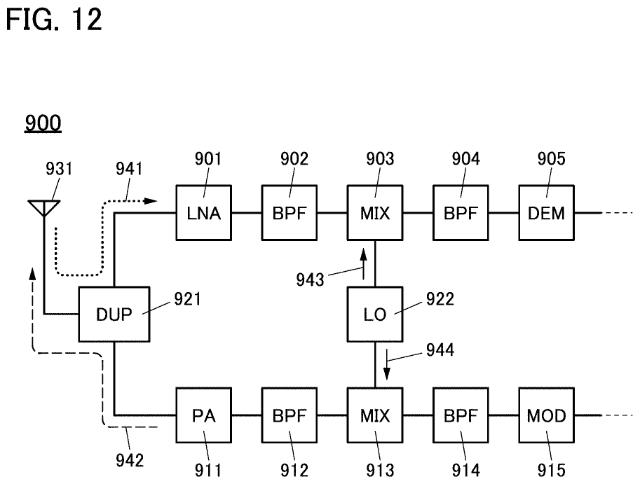

FIG. 12 is a diagram showing a structure example of a wireless transmission/reception device 900 as an example of the transmission/reception device 20D. The wireless transmission/reception device 900 includes a low noise amplifier 901 (LNA), a band pass filter 902 (BPF), a mixer 903 (MIX), a band pass filter 904, a demodulator 905 (DEM), a power amplifier 911 (PA), a band pass filter 912, a mixer 913, a band pass filter 914, a modulator 915 (MOD), a duplexer 921 (DUP), a local oscillator 922 (LO), and an antenna 931. Note that the antenna 931 corresponds to the electrode 61d or the electrode 61e in FIG. 11.

### <Reception>

A signal 941 transmitted from another semiconductor device, a base station, or the like is input to the low noise amplifier 901 as a receiving signal through the antenna 931 and the duplexer 921. The duplexer 921 has a function of transmitting and receiving a radio signal with one antenna.

The low noise amplifier 901 has a function of amplifying a weak receiving signal to a signal having intensity that can be processed by the wireless transmission/reception device 900. The signal 941 amplified by the low noise amplifier 901 is supplied to the mixer 903 through the band pass filter 902.

The band pass filter 902 has a function of attenuating frequency components outside a required frequency band among frequency components included in the signal 941 and transmitting the required frequency band.

The mixer 903 has a function of mixing the signal 941 transmitted through the band pass filter 902 and a signal 943 generated in the local oscillator 922 by a superheterodyne method. The mixer 903 mixes the signal 941 and the signal 943 and supplies a signal having a frequency component of a difference between them and a frequency component of the sum of them to the band pass filter 904.

The band pass filter 904 has a function of transmitting one frequency of the two frequency components. For example, the band pass filter 904 transmits the frequency component of the difference. Moreover, the band pass filter 904 also has a function of removing a noise component generated in the mixer 903. The signal transmitted through the band pass filter 904 is supplied to the demodulator 905. The demodulator 905 has a function of converting the supplied signal into a control signal, a data signal, or the like and outputting the control signal, the data signal, or the like. The signal output from the demodulator 905 is supplied to a variety of processing devices (an arithmetic device, a memory device, or the like).

### <Transmission>

The modulator 915 has a function of generating a basic signal to transmit a control signal, a data signal, or the like from the wireless transmission/reception device 900 to another semiconductor device, a base station, or the like. The basic signal is supplied to the mixer 913 through the band pass filter 914.

The band pass filter 914 has a function of removing a noise component generated when the basic signal is generated in the modulator 915.

The mixer 913 has a function of mixing the basic signal transmitted through the band pass filter 914 and a signal 944 generated in the local oscillator 922 by the superheterodyne method. The mixer 913 mixes the basic signal and the signal 944 and supplies a signal having a frequency component of a difference between them and a frequency component of the sum of them to the band pass filter 912.

The band pass filter 912 has a function of transmitting one frequency of the two frequency components. For example, the band pass filter 912 transmits the frequency component of the sum. Moreover, the band pass filter 912 also has a function of removing a noise component generated in the mixer 913. The signal transmitted through the band pass filter 912 is supplied to the power amplifier 911.

The power amplifier 911 has a function of amplifying a supplied signal to generate a signal 942. The signal 942 is radiated to the outside from the antenna 931 through the duplexer 921.

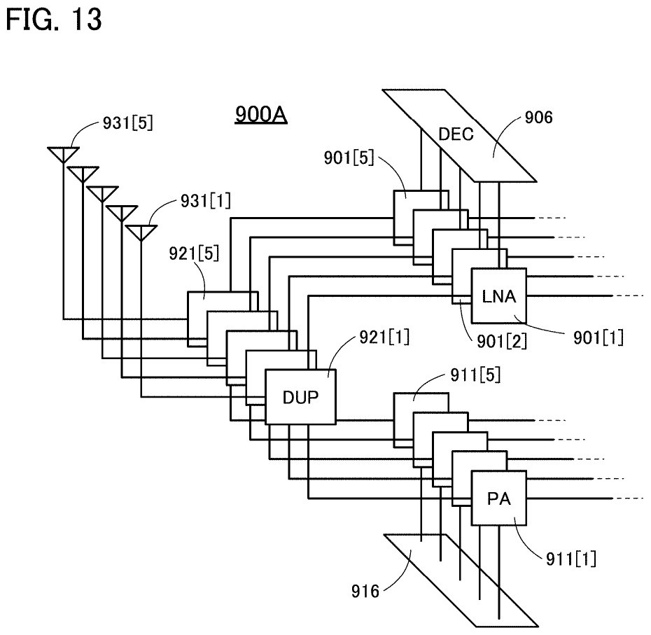

A wireless transmission/reception device 900A, which is a modification example of the above-described wireless transmission/reception device 900, will be described with reference to FIG. 13. In order to avoid repeated description, a description is mainly given to parts of the wireless transmission/reception device 900A that are different from those of the wireless transmission/reception device 900.

The wireless transmission/reception device 900A includes a plurality of antennas 931 compatible with 5G communication standard. A plurality of duplexers 921, a plurality of low-noise amplifiers 901, and a plurality of power amplifiers 911 are also included. The wireless transmission/reception device 900A includes a decoder circuit 906 (DEC) and a decoder circuit 916.

FIG. 13 illustrates a case where five pieces of each of the antenna 931, the duplexer 921, the low-noise amplifier 901, and the power amplifier 911. In FIG. 13, the first antenna 931 is denoted as an antenna 931[1], and the fifth antenna 931 is denoted as an antenna 931[5]. The duplexer 921, the low-noise amplifier 901, and the power amplifier 911 are also denoted in a manner similar to the antenna 931. Note that the number of the antenna 931, the duplexer 921, the low-noise amplifier 901, and the power amplifier 911 is not limited to five.

The antenna 931[1] is electrically connected to the duplexer 921[1]. The duplexer 921[1] is electrically connected to the low-noise amplifier 901[1] and the power amplifier 911[1]. The antenna 931[5] is electrically connected to the duplexer 921[5]. The duplexer 921[5] is electrically connected to the low-noise amplifier 901[5] and the power amplifier 911[5]. The second to fourth antennas 931 are also electrically connected to the second to fourth duplexers 921 like the antenna 931[1]. In addition, the second to fourth duplexers 921 are also electrically connected to the second to fourth low-noise amplifiers 901 and the second to fourth power amplifiers 911 like the duplexer 921[1].

The decoder circuit 906 is electrically connected to the plurality of low-noise amplifiers 901. In FIG. 13, five low-noise amplifiers 901 are connected to the decoder circuit 906. The decoder circuit 916 is electrically connected to the plurality of power amplifiers 911. In FIG. 13, five power amplifiers 911 are connected to the decoder circuit 916.

The decoder circuit 906 has a function of selecting any one or more of the low-noise amplifier 901[1] to the low-noise amplifier 901[5]. The decoder circuit 906 has a function of sequentially selecting the low-noise amplifier 901[1] to the low-noise amplifier 901[5]. Similarly, the decoder circuit 916 has a function of selecting any one or more of the power amplifier 911[1] to the power amplifier 911[5]. The decoder circuit 916 has a function of sequentially selecting the power amplifier 911[1] to the power amplifier 911[5].

For example, in the case of a display device included in a wearable electronic device such as a head-mounted display, a display device that is small, lightweight, capable of high-speed communication, or capable of displaying a high-resolution image is needed. Furthermore, even when the environment or place where a head-mounted display is used is changed, stable high-speed communication needs to be provided. In the case of a display device included in a wearable electronic device, there is a problem of an increase in the amount of image data for enabling the display device to display a high-resolution image.

Thus, when the layer L1 including the source driver and the like is bonded under the layer L2 layer including the display region with a free shape, a display device or the like with a free shape can be provided. Alternatively, a display device or the like having a novel structure in which the display device 10 includes antennas corresponding to a plurality of frequency bands can be provided. Alternatively, since the display device 10 includes the antennas, a display device or the like with high productivity can be provided. As described above, since the display device includes the pixel, the gate driver, the source driver, and the antennas as components, the number of components used for an electronic device can be reduced.

The composition, structure, method, and the like described in this embodiment can be used in an appropriate combination with the compositions, structures, methods, and the like described in the other embodiments and the like.

### Embodiment 3

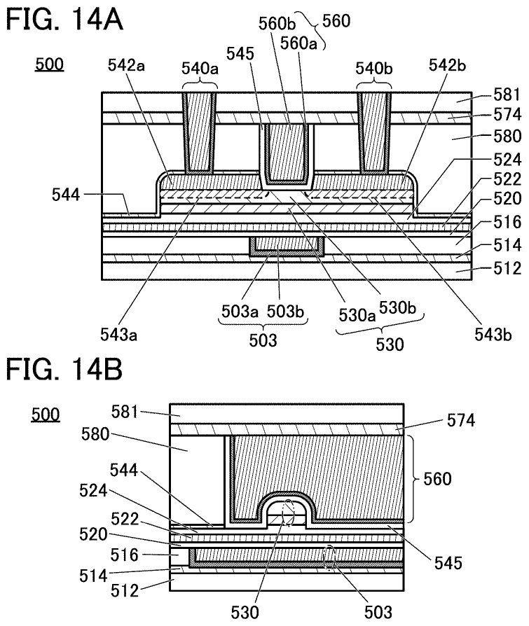

In this embodiment, structures of transistors that can be applied to the display device described in the above embodiment are described. FIG. 14A and FIG. 14B are diagrams showing a structure example of a transistor 500 included in the display device. FIG. 14A is a schematic cross-sectional view of the transistor 500 in the channel length direction, and FIG. 14B is a schematic cross-sectional view of the transistor 500 in the channel width direction.

Note that the transistor 500 is an example and the structure is not limited thereto; an appropriate transistor can be used in accordance with a circuit structure or a driving method. In the case where a semiconductor device is a single-polarity circuit using only OS transistors (which represents a circuit with transistors having the same polarity, e.g., only n-channel transistors), for example, the semiconductor device can be used for a pixel, a gate driver, a source driver, a memory, or the like.

As illustrated in FIG. 14A and FIG. 14B, the transistor 500 includes the conductor 503 positioned to be embedded in the insulator 514 and the insulator 516; an insulator 520 positioned over the insulator 516 and the conductor 503; an insulator 522 positioned over the insulator 520; an insulator 524 positioned over the insulator 522; an oxide 530a positioned over the insulator 524; an oxide 530b positioned over the oxide 530a; a conductor 542a and a conductor 542b positioned apart from each other over the oxide 530b; an insulator 580 that is positioned over the conductor 542a and the conductor 542b and is provided with an opening formed to overlap with a region between the conductor 542a and the conductor 542b; an insulator 545 positioned on a bottom surface and a side surface of an opening; and a conductor 560 positioned on a formation surface of the insulator 545.

In addition, as illustrated in FIG. 14A and FIG. 14B, an insulator 544 is preferably positioned between the insulator 580 and the oxide 530a, the oxide 530b, the conductor 542a, and the conductor 542b. Furthermore, as illustrated in FIG. 14A and FIG. 14B, the conductor 560 preferably includes a conductor 560a provided on an inner side than the insulator 545 and a conductor 560b provided to be embedded on the inner side of the conductor 560a. Moreover, as illustrated in FIG. 14A and FIG. 14B, an insulator 574 is preferably positioned over the insulator 580, the conductor 560, and the insulator 545.

Note that in this specification and the like, the oxide 530a and the oxide 530b are sometimes collectively referred to as an oxide 530.

Note that although a structure of the transistor 500 in which two layers of the oxide 530a and the oxide 530b are stacked in a region where a channel is formed and its vicinity is illustrated, the present invention is not limited thereto. For example, it is possible to employ a structure in which a single layer of the oxide 530b or a stacked-layer structure of three or more layers is provided.

Furthermore, although the conductor 560 is illustrated to have a stacked-layer structure of two layers in the transistor 500, the present invention is not limited thereto. For example, the conductor 560 may have a single-layer structure or a stacked-layer structure of three or more layers.

Here, the conductor 560 functions as a gate electrode of the transistor, and the conductor 542a and the conductor 542b each function as a source electrode or a drain electrode. As described above, the conductor 560 is formed to be embedded in the opening of the insulator 580 and the region between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be positioned between the source electrode and the drain electrode in a self-aligned manner. Therefore, the conductor 560 can be formed without an alignment margin, resulting in a reduction in the area occupied by the transistor 500. Accordingly, miniaturization and high integration of the semiconductor device can be achieved.

In addition, since the conductor 560 is formed in the region between the conductor 542a and the conductor 542b in a self-aligned manner, the conductor 560 does not have a region overlapping with the conductor 542a or the conductor 542b. Thus, parasitic capacitance formed between the conductor 560 and each of the conductor 542a and the conductor 542b can be reduced. As a result, the switching speed of the transistor 500 can be improved, and the transistor 500 can have high frequency characteristics.

The conductor 560 functions as a first gate (also referred to as top gate) electrode in some cases. The conductor 503 functions as a second gate (also referred to as bottom gate) electrode in some cases. In that case, the threshold voltage of the transistor 500 can be controlled by changing a voltage applied to the conductor 503 independently of a voltage applied to the conductor 560. In particular, the threshold voltage of the transistor 500 can be higher than 0 V and the off-state current can be reduced by applying a negative voltage to the conductor 503. Thus, a drain current at the time when a voltage applied to the conductor 560 is 0 V can be lower in the case where a negative voltage is applied to the conductor 503 than in the case where a negative voltage is not applied to the conductor 503.

The conductor 503 is positioned to overlap with the oxide 530 and the conductor 560. Thus, in the case where voltages are applied to the conductor 560 and the conductor 503, an electric field generated from the conductor 560 and an electric field generated from the conductor 503 are connected, so that a channel formation region formed in the oxide 530 can be covered.

In this specification and the like, a transistor structure in which a channel formation region is electrically surrounded by electric fields of a pair of gate electrodes (a first gate electrode and a second gate electrode) is referred to as a surrounded channel (S-channel) structure. Furthermore, in this specification and the like, the surrounded channel (S-channel) structure has a feature in that the side surface and the vicinity of the oxide 530 that is in contact with the conductor 542a and the conductor 542b functioning as a source electrode and a drain electrode are of i-type like the channel formation region. Since the side surface and the vicinity of the oxide 530 that is in contact with the conductor 542a and the conductor 542b are in contact with the insulator 544, they can be of i-type like the channel formation region. Note that in this specification and the like, “i-type” can be equated with “highly purified intrinsic” to be described later. The S-channel structure disclosed in this specification and the like is different from a Fin-type structure and a planar structure. With the S-channel structure, resistance to a short-channel effect can be enhanced, that is, a transistor in which a short-channel effect is unlikely to occur can be provided.

In addition, a conductor 503a is formed in contact with an inner wall of an opening in the insulator 514 and the insulator 516, and a conductor 503b is formed on the inner side. Note that although the transistor 500 having a structure in which the conductor 503a and the conductor 503b are stacked is illustrated, the present invention is not limited thereto. For example, the conductor 503 may be provided as a single layer or to have a stacked-layer structure of three or more layers. A metal oxide such as aluminum oxide, hafnium oxide, or tantalum oxide is preferably used for the insulator 514.

Here, for the conductor 503a, a conductive material that has a function of inhibiting diffusion of impurities such as a hydrogen atom, a hydrogen molecule, a water molecule, and a copper atom (through which the impurities are unlikely to pass) is preferably used. Alternatively, it is preferable to use a conductive material that has a function of inhibiting diffusion of oxygen (e.g., at least one of an oxygen atom, an oxygen molecule, and the like) (through which oxygen is unlikely to pass). Note that in this specification, a function of inhibiting diffusion of impurities or oxygen means a function of inhibiting diffusion of any one or all of the impurities and oxygen.

For example, when the conductor 503a has a function of inhibiting diffusion of oxygen, a reduction in conductivity of the conductor 503b due to oxidation can be inhibited.

In addition, in the case where the conductor 503 also functions as a wiring, a conductive material with high conductivity that contains tungsten, copper, or aluminum as its main component is preferably used for the conductor 503b. Note that although the conductor 503 has a stacked layer of the conductor 503a and the conductor 503b in this embodiment, the conductor 503 may have a single-layer structure.

The insulator 520, the insulator 522, and the insulator 524 have a function of a second gate insulating film.

Here, as the insulator 524 that is in contact with the oxide 530, an insulator that contains oxygen more than oxygen in the stoichiometric composition is preferably used. Such oxygen is easily released from the insulator by heating. In this specification and the like, oxygen released by heating is sometimes referred to as excess oxygen. That is, a region containing excess oxygen (also referred to as an excess-oxygen region) is preferably formed in the insulator 524. When such an insulator containing excess oxygen is provided in contact with the oxide 530, oxygen vacancies (V_{O}) in the oxide 530 can be reduced and the reliability of the transistor 500 can be improved. When hydrogen enters the oxygen vacancies in the oxide 530, such defects (hereinafter, referred to as V_{O}H in some cases) serve as donors and generate electrons serving as carriers in some cases. In other cases, bonding of part of hydrogen to oxygen bonded to a metal atom generates electrons serving as carriers. Thus, a transistor including an oxide semiconductor that contains a large amount of hydrogen is likely to have normally-on characteristics. Moreover, hydrogen in an oxide semiconductor is easily transferred by a stress such as heat or an electric field; thus, a large amount of hydrogen in an oxide semiconductor might reduce the reliability of the transistor. In one embodiment of the present invention, V_{O}H in the oxide 530 is preferably reduced as much as possible so that the oxide 530 becomes a highly purified intrinsic or substantially highly purified intrinsic oxide. It is important to remove impurities such as moisture or hydrogen in an oxide semiconductor (sometimes described as “dehydration” or “dehydrogenation treatment”) and to compensate for oxygen vacancies by supplying oxygen to the oxide semiconductor (sometimes described as “oxygen adding treatment”) in order to obtain an oxide semiconductor whose V_{O}H is sufficiently reduced. When an oxide semiconductor with sufficiently reduced impurities such as V_{O}H is used for a channel formation region of a transistor, the transistor can have stable electrical characteristics.

As the insulator including an excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably within the range of 100° C. to 700° C., or 100° C. to 400° C.

One or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when a reaction in which a bond of V_{O}H is cut occurs, i.e., a reaction of V_{O}H→V_{O}+H occurs. Part of hydrogen generated at this time is bonded to oxygen to be H₂O, and removed from the oxide 530 or an insulator near the oxide 530 in some cases. Some hydrogen may be gettered into the conductor 542a and the conductor 542b in some cases.

For the microwave treatment, for example, an apparatus including a power supply that generates high-density plasma or an apparatus including a power supply that applies RF to the substrate side is suitably used. For example, the use of an oxygen-containing gas and high-density plasma enables high-density oxygen radicals to be generated, and application of the RF to the substrate side allows the oxygen radicals generated by the high-density plasma to be efficiently introduced into the oxide 530 or an insulator in the vicinity of the oxide 530. The pressure in the microwave treatment is higher than or equal to 133 Pa, preferably higher than or equal to 200 Pa, further preferably higher than or equal to 400 Pa. As a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In a manufacturing process of the transistor 500, heat treatment is preferably performed with the surface of the oxide 530 exposed. The heat treatment is performed at higher than or equal to 100° C. and lower than or equal to 450° C., preferably higher than or equal to 350° C. and lower than or equal to 400° C., for example. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 530 to reduce oxygen vacancies (V_{O}). The heat treatment may be performed under reduced pressure. Alternatively, the heat treatment may be performed in such a manner that heat treatment is performed in a nitrogen gas or inert gas atmosphere, and then another heat treatment is performed in an atmosphere containing an oxidizing gas at 10 ppm or more, 1% or more, or 10% or more in order to compensate for released oxygen. Alternatively, the heat treatment may be performed in such a manner that heat treatment is performed in an atmosphere containing an oxidizing gas at 10 ppm or more, 1% or more, or 10% or more, and then another heat treatment is successively performed in a nitrogen gas or inert gas atmosphere.

Note that the oxygen adding treatment performed on the oxide 530 can promote a reaction in which oxygen vacancies in the oxide 530 are filled with supplied oxygen, i.e., a reaction of V_{O}+O→null. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of V_{O}H.

In addition, in the case where the insulator 524 includes an excess-oxygen region, it is preferable that the insulator 522 have a function of inhibiting diffusion of oxygen (e.g., an oxygen atom, an oxygen molecule, or the like) (through which oxygen is unlikely to pass).

When the insulator 522 has a function of inhibiting diffusion of oxygen or impurities, oxygen contained in the oxide 530 is not diffused into the insulator 520 side, which is preferable. Furthermore, the conductor 503 can be inhibited from reacting with oxygen contained in the insulator 524 or the oxide 530.

For the insulator 522, a single layer or stacked layers of an insulator containing what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr)TiO₃ (BST) are preferably used, for example. As miniaturization and high integration of transistors progress, a problem such as leakage current might arise because of a thinner gate insulating film. When a high-k material is used for an insulator functioning as the gate insulating film, a gate voltage during transistor operation can be reduced while the physical thickness is maintained.

It is particularly preferable to use an insulator containing an oxide of one or both of aluminum and hafnium, which is an insulating material having a function of inhibiting diffusion of impurities, oxygen, and the like (through which oxygen is unlikely to pass). Aluminum oxide, hafnium oxide, an oxide containing aluminum and hafnium (hafnium aluminate), or the like is preferably used as the insulator containing an oxide of one or both of aluminum and hafnium. In the case where the insulator 522 is formed using such a material, the insulator 522 functions as a layer that inhibits release of oxygen from the oxide 530 and mixing of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. The insulator over which silicon oxide, silicon oxynitride, or silicon nitride is stacked may be used.

In addition, it is preferable that the insulator 520 be thermally stable. For example, silicon oxide and silicon oxynitride are suitable because they are thermally stable. Furthermore, the combination of an insulator that is a high-k material and silicon oxide or silicon oxynitride enables the insulator 520 to have a stacked-layer structure that has thermal stability and a high dielectric constant.

Note that in the transistor 500 in FIG. 14A and FIG. 14B, the insulator 520, the insulator 522, and the insulator 524 are shown as the second gate insulating film having a stacked-layer structure of three layers; however, the second gate insulating film may be a single layer or may have a stacked-layer structure of two layers or four or more layers. In such cases, without limitation to a stacked-layer structure formed of the same material, a stacked-layer structure formed of different materials may be employed.

In the transistor 500, a metal oxide functioning as an oxide semiconductor is used as the oxide 530 including a channel formation region. Note that the oxide semiconductor preferably contains at least one of In and Zn. For example, as the oxide 530, a metal oxide such as an In-M-Zn oxide (the element M is one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is preferably used.

The metal oxide functioning as an oxide semiconductor may be formed by a sputtering method or an ALD (Atomic Layer Deposition) method. Note that the metal oxide functioning as an oxide semiconductor will be described in detail in another embodiment.

The metal oxide functioning as the channel formation region in the oxide 530 has a band gap that is preferably 2 eV or higher, further preferably 2.5 eV or higher. With use of a metal oxide having such a wide band gap, the off-state current of the transistor can be reduced.

When the oxide 530 includes the oxide 530a under the oxide 530b, it is possible to inhibit diffusion of impurities into the oxide 530b from the components formed below the oxide 530a.

Note that the oxide 530 preferably has a stacked-layer structure of a plurality of oxide layers that differ in the atomic ratio of metal atoms. Specifically, the atomic ratio of the element M to the constituent elements in the metal oxide used as the oxide 530a is preferably higher than the atomic ratio of the element M to the constituent elements in the metal oxide used as the oxide 530b. In addition, the atomic ratio of the element M to In in the metal oxide used as the oxide 530a is preferably higher than the atomic ratio of the element M to In in the metal oxide used as the oxide 530b. Furthermore, the atomic ratio of In to the element M in the metal oxide used as the oxide 530b is preferably higher than the atomic ratio of In to the element M in the metal oxide used as the oxide 530a.

The energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gently changes at a junction portion between the oxide 530a and the oxide 530b. In other words, the energy level of the conduction band minimum at the junction portion between the oxide 530a and the oxide 530b continuously changes or is continuously connected. This can be obtained by decreasing the density of defect states in a mixed layer formed at the interface between the oxide 530a and the oxide 530b.

Specifically, when the oxide 530a and the oxide 530b contain a common element (as a main component) in addition to oxygen, a mixed layer with a low density of defect states can be formed. For example, in the case where the oxide 530b is an In-Ga—Zn oxide, an In-Ga—Zn oxide, a Ga—Zn oxide, gallium oxide, or the like is used as the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 500 can have a high on-state current.

The conductor 542a and the conductor 542b functioning as the source electrode and the drain electrode are provided over the oxide 530b. For the conductor 542a and conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing the above metal element; an alloy containing a combination of the above metal element; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. Furthermore, a metal nitride film of tantalum nitride or the like is preferable because it has a barrier property against hydrogen or oxygen.

In addition, although the conductor 542a and the conductor 542b each having a single-layer structure are shown in FIG. 14A, a stacked-layer structure of two or more layers may be employed. For example, it is preferable to stack a tantalum nitride film and a tungsten film. Alternatively, a titanium film and an aluminum film may be stacked. Alternatively, a two-layer structure in which an aluminum film is stacked over a tungsten film, a two-layer structure in which a copper film is stacked over a copper-magnesium-aluminum alloy film, a two-layer structure in which a copper film is stacked over a titanium film, or a two-layer structure in which a copper film is stacked over a tungsten film may be employed.

Other examples include a three-layer structure in which a titanium film or a titanium nitride film is formed, an aluminum film or a copper film is stacked over the titanium film or the titanium nitride film, and a titanium film or a titanium nitride film is formed thereover; and a three-layer structure in which a molybdenum film or a molybdenum nitride film is formed, an aluminum film or a copper film is stacked over the molybdenum film or the molybdenum nitride film, and a molybdenum film or a molybdenum nitride film is formed thereover. Note that a transparent conductive material containing indium oxide, tin oxide, or zinc oxide may be used.

In addition, as shown in FIG. 14A, a region 543a and a region 543b are sometimes formed as low-resistance regions at an interface between the oxide 530 and the conductor 542a (the conductor 542b) and in the vicinity of the interface. In that case, the region 543a functions as one of a source region and a drain region, and the region 543b functions as the other of the source region and the drain region. Furthermore, the channel formation region is formed in a region between the region 543a and the region 543b.

When the conductor 542a (the conductor 542b) is provided to be in contact with the oxide 530, the oxygen concentration in the region 543a (the region 543b) sometimes decreases. In addition, a metal compound layer that contains the metal contained in the conductor 542a (the conductor 542b) and the component of the oxide 530 is sometimes formed in the region 543a (the region 543b). In such a case, the carrier density of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. At this time, the insulator 544 may be provided to cover a side surface of the oxide 530 and to be in contact with the insulator 524.

A metal oxide containing one kind or two or more kinds selected from hafnium, aluminum, gallium, yttrium, zirconium, tungsten, titanium, tantalum, nickel, germanium, neodymium, lanthanum, magnesium, and the like can be used as the insulator 544. Alternatively, silicon nitride oxide, silicon nitride, or the like can be used for the insulator 544.

It is particularly preferable to use an insulator containing an oxide of one or both of aluminum and hafnium, such as aluminum oxide, hafnium oxide, or an oxide containing aluminum and hafnium (hafnium aluminate), as the insulator 544. In particular, hafnium aluminate has higher heat resistance than a hafnium oxide film. Therefore, hafnium aluminate is preferable because it is unlikely to be crystallized by heat treatment in a later step. Note that the insulator 544 is not an essential component when the conductor 542a and the conductor 542b are oxidation-resistant materials or do not significantly lose their conductivity even after absorbing oxygen. Design is appropriately set in consideration of required transistor characteristics.

When the insulator 544 is included, diffusion of impurities such as water and hydrogen contained in the insulator 580 into the oxide 530b through the insulator 545 can be inhibited. Furthermore, oxidation of the conductor 560 due to excess oxygen contained in the insulator 580 can be inhibited.

The insulator 545 functions as a first gate insulating film. Like the insulator 524, the insulator 545 is preferably formed using an insulator that contains excess oxygen and releases oxygen by heating.

Specifically, silicon oxide containing excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride are preferable because they are thermally stable.

When an insulator containing excess oxygen is provided as the insulator 545, oxygen can be effectively supplied from the insulator 545 to the channel formation region of the oxide 530b. Furthermore, as in the insulator 524, the concentration of impurities such as water or hydrogen in the insulator 545 is preferably reduced. The thickness of the insulator 545 is preferably greater than or equal to 1 nm and less than or equal to 20 nm.

Furthermore, to efficiently supply excess oxygen contained in the insulator 545 to the oxide 530, a metal oxide may be provided between the insulator 545 and the conductor 560. The metal oxide preferably inhibits diffusion of oxygen from the insulator 545 to the conductor 560. Providing the metal oxide that inhibits diffusion of oxygen inhibits diffusion of excess oxygen from the insulator 545 to the conductor 560. That is, reduction in the amount of excess oxygen supplied to the oxide 530 can be inhibited. Moreover, oxidation of the conductor 560 due to excess oxygen can be inhibited. For the metal oxide, a material that can be used for the insulator 544 is used.

Note that the insulator 545 may have a stacked-layer structure like the second gate insulating film. As miniaturization and high integration of transistors progress, a problem such as leakage current might arise because of a thinner gate insulating film. For that reason, when the insulator functioning as the gate insulating film has a stacked-layer structure of a high-k material and a thermally stable material, a gate voltage during transistor operation can be reduced while the physical thickness is maintained. Furthermore, the stacked-layer structure can be thermally stable and have a high relative permittivity.

Although the conductor 560 that functions as the first gate electrode and has a two-layer structure is shown in FIG. 14A and FIG. 14B, a single-layer structure or a stacked-layer structure of three or more layers may be employed.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, it is possible to inhibit a reduction in conductivity of the conductor 560b due to oxidation caused by oxygen contained in the insulator 545. As a conductive material having a function of inhibiting diffusion of oxygen, for example, tantalum, tantalum nitride, ruthenium, ruthenium oxide, or the like is preferably used. For the conductor 560a, the oxide semiconductor that can be used as the oxide 530 can be used. In that case, when the conductor 560b is deposited by a sputtering method, the conductor 560a can have a reduced electrical resistance value to be a conductor. Such a conductor can be referred to as an OC (Oxide Conductor) electrode.

In addition, a conductive material containing tungsten, copper, or aluminum as its main component is preferably used for the conductor 560b. Furthermore, the conductor 560b also functions as a wiring and thus a conductor having high conductivity is preferably used as the conductor 560b. For example, a conductive material containing tungsten, copper, or aluminum as its main component can be used. The conductor 560b may have a stacked-layer structure, for example, a stacked-layer structure of any of the above conductive materials and titanium or titanium nitride.

The insulator 580 is provided over the conductor 542a and the conductor 542b with the insulator 544 therebetween. The insulator 580 preferably includes an excess-oxygen region. For example, the insulator 580 preferably contains silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, resin, or the like. In particular, silicon oxide and silicon oxynitride are preferable because they are thermally stable. In particular, silicon oxide and porous silicon oxide are preferable because an excess-oxygen region can be easily formed in a later step.

The insulator 580 preferably includes an excess-oxygen region. When the insulator 580 that releases oxygen by heating is provided, oxygen in the insulator 580 can be efficiently supplied to the oxide 530. Note that the concentration of impurities such as water or hydrogen in the insulator 580 is preferably reduced.

The opening of the insulator 580 is formed to overlap with the region between the conductor 542a and the conductor 542b. Accordingly, the conductor 560 is formed to be embedded in the opening of the insulator 580 and the region between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580; thus, even when the conductor 560 has a shape with a high aspect ratio, the conductor 560 can be formed without collapsing during the process.

The insulator 574 is preferably provided in contact with a top surface of the insulator 580, atop surface of the conductor 560, and atop surface of the insulator 545. When the insulator 574 is deposited using a sputtering method, excess-oxygen regions can be provided in the insulator 545 and the insulator 580. Accordingly, oxygen can be supplied from the excess-oxygen regions to the oxide 530.

For example, a metal oxide containing one kind or two or more kinds selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness of greater than or equal to 0.5 nm and less than or equal to 3.0 nm can inhibit diffusion of hydrogen and nitrogen. Accordingly, aluminum oxide deposited by a sputtering method serves as an oxygen supply source and can also have a function of a barrier film against impurities such as hydrogen.

In addition, an insulator 581 functioning as an interlayer film is preferably provided over the insulator 574. As in the insulator 524 or the like, the concentration of impurities such as water or hydrogen in the insulator 581 is preferably reduced.

Furthermore, a conductor 540a and a conductor 540b are positioned in openings formed in the insulator 581, the insulator 574, the insulator 580, and the insulator 544. The conductor 540a and the conductor 540b are provided to face each other with the conductor 560 therebetween.

In particular, aluminum oxide has an excellent blocking effect that prevents the passage of both oxygen and impurities such as hydrogen or moisture which are factors of change in electrical characteristics of the transistor. Accordingly, aluminum oxide can prevent mixing of impurities such as hydrogen or moisture into the transistor 500 in the manufacturing process and after the manufacturing of the transistor. In addition, release of oxygen from the oxide included in the transistor 500 can be inhibited. Therefore, aluminum oxide is suitably used for the protective film of the transistor 500.

After the transistor 500 is formed, an opening may be formed to surround the transistor 500 and an insulator having a high barrier property against hydrogen or water may be formed to cover the opening. Surrounding the transistor 500 with the insulator having a high barrier property can prevent entry of moisture and hydrogen from the outside. Alternatively, a plurality of transistors 500 may be collectively surrounded by the insulator having a high barrier property against hydrogen or water. When an opening is formed to surround the transistor 500, for example, the formation of an opening reaching the insulator 522 or the insulator 514 and the formation of the insulator having a high barrier property in contact with the insulator 522 or the insulator 514 are suitable because these formation steps can also serve as part of the manufacturing steps of the transistor 500. The insulator having a high barrier property against hydrogen or water is formed using a material similar to that for the insulator 522 or the insulator 514, for example.

With use of this structure, a semiconductor device using a transistor including an oxide semiconductor can be miniaturized or highly integrated.

Examples of a substrate that can be used for the semiconductor device of one embodiment of the present invention include a glass substrate, a quartz substrate, a sapphire substrate, a ceramic substrate, a metal substrate (e.g., a stainless steel substrate, a substrate including stainless steel foil, a tungsten substrate, and a substrate including tungsten foil), a semiconductor substrate (e.g., a single crystal semiconductor substrate, a polycrystalline semiconductor substrate, and a compound semiconductor substrate), and an SOI (Silicon on Insulator) substrate. Alternatively, a plastic substrate having heat resistance to the processing temperature in this embodiment may be used. Examples of a glass substrate include a barium borosilicate glass substrate, an aluminosilicate glass substrate, an aluminoborosilicate glass substrate, and a soda lime glass substrate. Alternatively, crystallized glass or the like can be used.

Alternatively, a flexible substrate, an attachment film, paper including a fibrous material, a base film, or the like can be used as the substrate. As examples of the flexible substrate, the attachment film, the base material film, and the like, the following can be given. Examples include plastics typified by polyethylene terephthalate (PET), polyethylene naphthalate (PEN), polyether sulfone (PES), and polytetrafluoroethylene (PTFE). Another example is a synthetic resin such as acrylic. Other examples are polypropylene, polyester, polyvinyl fluoride, and polyvinyl chloride. Other examples are polyamide, polyimide, an aramid resin, an epoxy resin, an inorganic vapor deposition film, paper, and the like. In particular, the use of a semiconductor substrate, a single crystal substrate, an SOI substrate, or the like enables the manufacture of small-sized transistors with a small variation in characteristics, size, shape, or the like and with high current capability. When a circuit is formed with such transistors, lower power consumption of the circuit or higher integration of the circuit can be achieved.

A flexible substrate may be used as the substrate, and a transistor, a resistor, a capacitor, and/or the like may be formed directly over the flexible substrate. Alternatively, a separation layer may be provided between the substrate and the transistor, the resistor, the capacitor, and/or the like. After part or the whole of a semiconductor device is completed over the separation layer, the separation layer can be used for separation from the substrate and transfer to another substrate. In such a case, the transistor, the resistor, the capacitor, and/or the like can be transferred to a substrate having low heat resistance or a flexible substrate. As the separation layer, a stack of inorganic films, namely a tungsten film and a silicon oxide film, an organic resin film of polyimide or the like formed over a substrate, or a silicon film containing hydrogen can be used, for example.

That is, a semiconductor device may be formed over one substrate and then transferred to another substrate. Examples of a substrate to which a semiconductor device is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), or the like), a leather substrate, and a rubber substrate. With use of any of these substrates, a flexible semiconductor device or a highly durable semiconductor device can be manufactured, high heat resistance can be provided, or a reduction in weight or thickness can be achieved.

Providing a semiconductor device over a flexible substrate can suppress an increase in weight and can produce a non-breakable semiconductor device.

### <Modification Example 1 of Transistor>

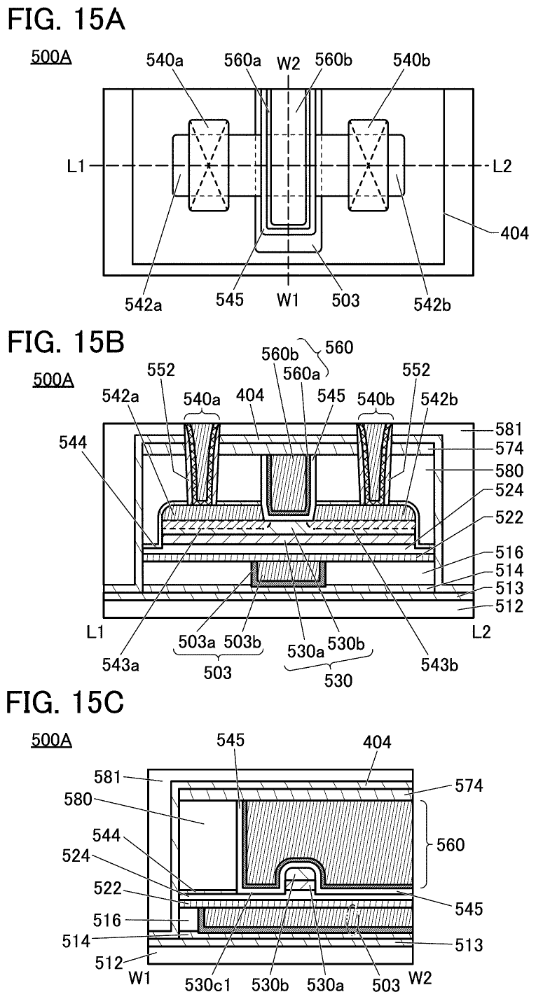

A transistor 500A illustrated in FIG. 15A, FIG. 15B, and FIG. 15C is a modification example of the transistor 500 having the structure illustrated in FIG. 14A and FIG. 14B. FIG. 15A is a top view of the transistor 500A. FIG. 15B is a schematic cross-sectional view of a portion indicated by dashed-dotted line L1-L2 in FIG. 15A. FIG. 15C is a schematic cross-sectional view of a portion indicated by dashed-dotted line W1-W2 in FIG. 15A. Note that for clarity of the drawing, some components are not illustrated in the top view in FIG. 15A. The structure illustrated in FIG. 15A, FIG. 15B, and FIG. 15C can also be used for other transistors included in the semiconductor device of one embodiment of the present invention.

The transistor 500A having the structure illustrated in FIG. 15A, FIG. 15B, and FIG. 15C is different from the transistor 500 having the structure illustrated in FIG. 14A and FIG. 14B in that an insulator 552, an insulator 513, and an insulator 404 are included. Furthermore, the transistor 500A is different from the transistor 500 having the structure illustrated in FIG. 14A and FIG. 14B in that the insulator 552 is provided in contact with a side surface of the conductor 540a and a side surface of the conductor 540b. Moreover, the transistor 500A is different from the transistor 500 having the structure illustrated in FIG. 14A and FIG. 14B in that the insulator 520 is not included.

In the transistor 500A having the structure illustrated in FIG. 15A, FIG. 15B, and FIG. 15C, the insulator 513 is provided over the insulator 512. The insulator 404 is provided over the insulator 574 and the insulator 513.

In the transistor 500A having the structure illustrated in FIG. 15A, FIG. 15B, and FIG. 15C, the insulator 514, the insulator 516, the insulator 522, the insulator 524, the insulator 544, the insulator 580, and the insulator 574 are patterned and covered with the insulator 404. That is, the insulator 404 is in contact with a top surface of the insulator 574, a side surface of the insulator 574, a side surface of the insulator 580, a side surface of the insulator 544, a side surface of the insulator 524, a side surface of the insulator 522, a side surface of the insulator 516, a side surface of the insulator 514, and a top surface of the insulator 513. Thus, the oxide 530 and the like are isolated from the outside by the insulator 404 and the insulator 513.

The insulator 513 and the insulator 404 preferably have high capability of inhibiting diffusion of hydrogen (e.g., at least one of a hydrogen atom, a hydrogen molecule, and the like) or a water molecule. For example, for the insulator 513 and the insulator 404, silicon nitride or silicon nitride oxide that is a material having a high hydrogen barrier property is preferably used. This can inhibit diffusion of hydrogen or the like into the oxide 530, thereby suppressing the degradation of the characteristics of the transistor 500A. Consequently, the reliability of the semiconductor device of one embodiment of the present invention can be increased.

The insulator 552 is provided in contact with the insulator 581, the insulator 404, the insulator 574, the insulator 580, and the insulator 544. The insulator 552 preferably has a function of inhibiting diffusion of hydrogen or water molecules. For example, for the insulator 552, an insulator such as silicon nitride, aluminum oxide, or silicon nitride oxide that is a material having a high hydrogen barrier property is preferably used. In particular, it is preferable to use silicon nitride as the insulator 552 because of its high hydrogen barrier property. The use of a material having a high hydrogen barrier property for the insulator 552 can inhibit diffusion of impurities such as water or hydrogen from the insulator 580 and the like into the oxide 530 through the conductor 540a and the conductor 540b. Furthermore, oxygen contained in the insulator 580 can be inhibited from being absorbed by the conductor 540a and the conductor 540b. As described above, the reliability of the semiconductor device of one embodiment of the present invention can be increased.

### <Modification Example 2 of Transistor>

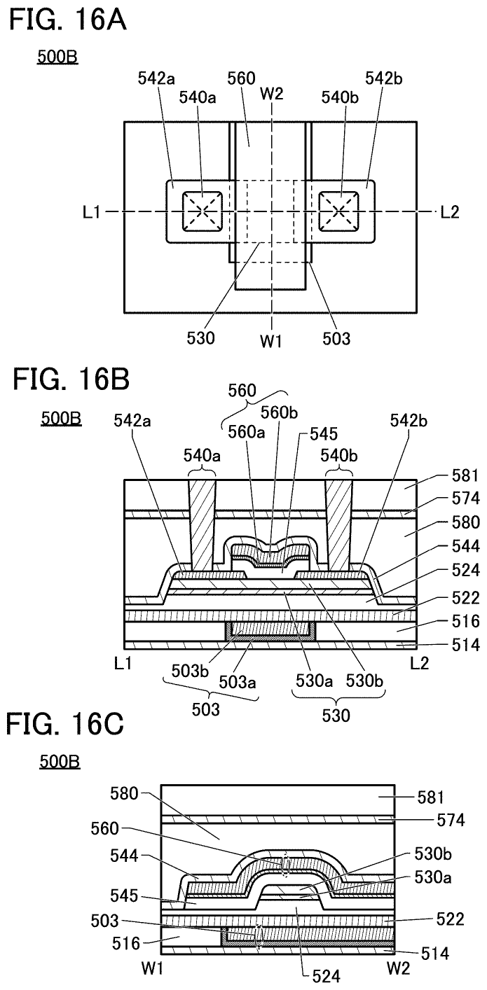

A structure example of a transistor 500B is described with reference to FIG. 16A, FIG. 16B, and FIG. 16C. FIG. 16A is a top view of the transistor 500B. FIG. 16B is a schematic cross-sectional view of a portion indicated by dashed-dotted line L1-L2 in FIG. 16A. FIG. 16C is a schematic cross-sectional view of a portion indicated by dashed-dotted line W1-W2 in FIG. 16A. Note that for clarity of the drawing, some components are not illustrated in the top view in FIG. 16A.

The transistor 500B is a modification example of the transistor 500 and can be replaced with the transistor 500. Thus, differences of the transistor 500B from the transistor 500 will be mainly described to avoid repeated description.

The conductor 560 functioning as a first gate electrode includes the conductor 560a and the conductor 560b over the conductor 560a. For the conductor 560a, it is preferable to use a conductive material having a function of inhibiting diffusion of impurities such as a hydrogen atom, a hydrogen molecule, a water molecule, and a copper atom. Alternatively, it is preferable to use a conductive material having a function of inhibiting diffusion of oxygen (e.g., at least one of an oxygen atom, an oxygen molecule, and the like).

When the conductor 560a has a function of inhibiting oxygen diffusion, the range of choices for the material of the conductor 560b can be extended. That is, the conductor 560a inhibits oxidation of the conductor 560b, thereby preventing the decrease in conductivity.

The insulator 544 is preferably provided to cover the top surface and the side surface of the conductor 560 and a side surface of the insulator 545. For the insulator 544, an insulating material having a function of inhibiting diffusion of oxygen and impurities such as water or hydrogen is preferably used. For example, aluminum oxide or hafnium oxide is preferably used. Moreover, it is possible to use, for example, a metal oxide such as magnesium oxide, gallium oxide, germanium oxide, yttrium oxide, zirconium oxide, lanthanum oxide, neodymium oxide, or tantalum oxide or silicon nitride oxide, silicon nitride, or the like.

The insulator 544 can inhibit oxidation of the conductor 560. Moreover, the insulator 544 can inhibit diffusion of impurities such as water and hydrogen contained in the insulator 580 into the transistor 500B.

The transistor 500B has the conductor 560 overlapping with part of the conductor 542a and part of the conductor 542b, and thus tends to have larger parasitic capacitance than the transistor 500. Consequently, the transistor 500B tends to have a lower operating frequency than the transistor 500. However, the transistor 500B does not require steps of providing an opening in the insulator 580 and the like and embedding the conductor 560, the insulator 545, and the like in the opening; hence, the productivity of the transistor 500B is higher than that of the transistor 500.

The composition, structure, method, and the like described in this embodiment can be used in an appropriate combination with the compositions, structures, methods, and the like described in the other embodiments and the like.

### Embodiment 4

In this embodiment, an oxide semiconductor which is a kind of metal oxides will be described.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

### <Classification of Crystal Structure>

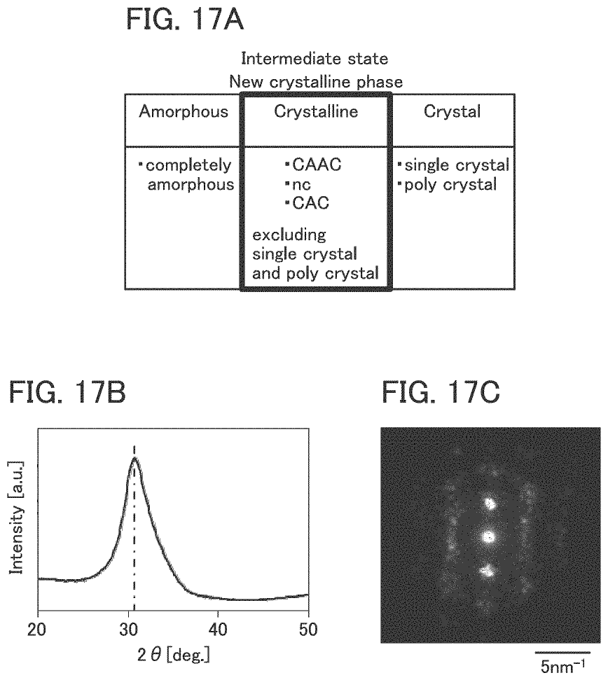

First, classifications of the crystal structures of an oxide semiconductor will be described with reference to FIG. 17A. FIG. 17A is a diagram showing the classification of crystal structures of an oxide semiconductor, typically IGZO (a metal oxide containing In, Ga, and Zn).

As shown in FIG. 17A, an oxide semiconductor is roughly classified into “Amorphous”, “Crystalline”, and “Crystal”. The term “Amorphous” includes completely amorphous. The term “Crystalline” includes CAAC (c-axis-aligned crystalline), nc (nanocrystalline), and CAC (cloud-aligned composite) (excluding single crystal and poly crystal). Note that the term “Crystalline” excludes single crystal, poly crystal, and completely amorphous. The term “Crystal” includes single crystal and poly crystal.

Note that the structures in the thick frame in FIG. 17A are in an intermediate state between “Amorphous” and “Crystal”, and belong to a new crystalline phase. That is, these structures are completely different from “Amorphous”, which is energetically unstable, and “Crystal”.

A crystal structure of a film or a substrate can be analyzed with an X-ray diffraction (XRD) spectrum. FIG. 17B shows an XRD spectrum, which is obtained by GIXD (Grazing-Incidence XRD) measurement, of a CAAC-IGZO film classified into “Crystalline” (the vertical axis represents intensity in arbitrary unit (a. u.)). Note that a GIXD method is also referred to as a thin film method or a Seemann-Bohlin method. The XRD spectrum that is shown in FIG. 17B and obtained by GIXD measurement is hereinafter simply referred to as an XRD spectrum. The CAAC-IGZO film in FIG. 17B has a composition in the vicinity of In:Ga:Zn=4:2:3 [atomic ratio]. The CAAC-IGZO film in FIG. 17B has a thickness of 500 nm.

As shown in FIG. 17B, a clear peak indicating crystallinity is detected in the XRD spectrum of the CAAC-IGZO film. Specifically, a peak indicating c-axis alignment is detected at 2θ of around 31° in the XRD spectrum of the CAAC-IGZO film. As shown in FIG. 17B, the peak at 2θ of around 310 is asymmetric with respect to the axis of the angle at which the peak intensity is detected.

A crystal structure of a film or a substrate can also be evaluated with a diffraction pattern obtained by a nanobeam electron diffraction (NBED) method (such a pattern is also referred to as a nanobeam electron diffraction pattern). FIG. 17C shows a diffraction pattern of the CAAC-IGZO film. FIG. 17C shows a diffraction pattern obtained with the NBED method in which an electron beam is incident in the direction parallel to the substrate. The composition of the CAAC-IGZO film in FIG. 17C is In:Ga:Zn=4:2:3 [atomic ratio] or the neighborhood thereof. In the nanobeam electron diffraction method, electron diffraction is performed with a probe diameter of 1 nm.

As shown in FIG. 17C, a plurality of spots indicating c-axis alignment are observed in the diffraction pattern of the CAAC-IGZO film.

### <<Structure of Oxide Semiconductor>>

Oxide semiconductors might be classified in a manner different from that in FIG. 17A when classified in terms of the crystal structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that the distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a stacked-layer structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear grain boundary is observed is what is called polycrystal. It is highly probable that the grain boundary becomes a recombination center and captures carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In-Ga—Zn oxide are suitable because they can inhibit generation of a grain boundary as compared with an In oxide.

The CAAC-OS is an oxide semiconductor with high crystallinity in which no clear grain boundary is observed. Thus, in the CAAC-OS, reduction in electron mobility due to the grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis using out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., 1 nm or larger and 30 nm or smaller).

[a-like OS]

The a-like OS is an oxide semiconductor having a structure between those of the nc-OS and the amorphous oxide semiconductor. The a-like OS includes a void or a low-density region. That is, the a-like OS has low crystallinity as compared with the nc-OS and the CAAC-OS. Moreover, the a-like OS has higher hydrogen concentration in the film than the nc-OS and the CAAC-OS.

### <<Structure of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic ratios of In, Ga, and Zn to the metal elements contained in the CAC-OS in an In-Ga—Zn oxide are denoted with [In], [Ga], and [Zn], respectively. For example, the first region in the CAC-OS in the In-Ga—Zn oxide has [In] higher than that in the composition of the CAC-OS film. Moreover, the second region has [Ga] higher than that in the composition of the CAC-OS film. For example, the first region has higher [In] and lower [Ga] than the second region. Moreover, the second region has higher [Ga] and lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

For example, energy dispersive X-ray spectroscopy (EDX) is used to obtain EDX mapping, and according to the EDX mapping, the CAC-OS in the In-Ga—Zn oxide can be found to have a structure in which the region containing In as its main component (the first region) and the region containing Ga as its main component (the second region) are unevenly distributed and mixed.

In the case where the CAC-OS is used for a transistor, a switching function (on/off switching function) can be given to the CAC-OS owing to the complementary action of the conductivity derived from the first region and the insulating property derived from the second region. A CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor with a low carrier concentration is preferably used for the transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Electric charge trapped by the trap states in the oxide semiconductor takes a long time to disappear and might behave like fixed electric charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained using SIMS, is lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained using SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained using SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

The composition, structure, method, and the like described in this embodiment can be used in an appropriate combination with the compositions, structures, methods, and the like described in the other embodiments.

### Embodiment 5

In this embodiment, a head-mounted display to which the display device of one embodiment of the present invention including a display region with a free shape can be applied will be described.

The display device of one embodiment of the present invention can be used for a display portion of a head-mounted display. As a result, the head-mounted display can have high display quality. The head-mounted display can have extremely high resolution. The head-mounted display can have high reliability.

The display device included in the head-mounted display may include an antenna. When a signal is received with the antenna, an image, information, or the like can be displayed on the display portion.

The head-mounted display may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, electric power, radiation, flow rate, humidity, gradient, oscillation, a smell, or infrared rays). The sensor is preferably a MEMS.

The head-mounted display can have a variety of functions. For example, the head-mounted display can have a function of displaying a variety of information (a still image, a moving image, a text image, and the like) on the display portion, a touch panel function, a function of displaying a calendar, date, time, and the like, a function of executing a variety of software (programs), a wireless communication function including 5G communication, and a function of reading out a program or data stored in a recording medium.

Furthermore, a head-mounted display including a plurality of display portions can have a function of displaying image data mainly on one display portion while displaying text data mainly on another display portion, a function of displaying a three-dimensional image by displaying images on a plurality of display portions with a parallax taken into account, or the like. Furthermore, a head-mounted display including an image receiving portion can have a function of taking a still image or a moving image, a function of automatically or manually correcting a taken image, a function of storing a taken image in a recording medium (an external recording medium or a recording medium incorporated in the head-mounted display), a function of displaying a taken image on a display portion, or the like. Note that functions of the head-mounted display of one embodiment of the present invention are not limited thereto, and the head-mounted display can have a variety of functions.

The display device of one embodiment of the present invention can display images with extremely high resolution. Thus, the head-mounted display can be suitably used for a VR (Virtual Reality) device, AR (Augmented Reality), and the like.

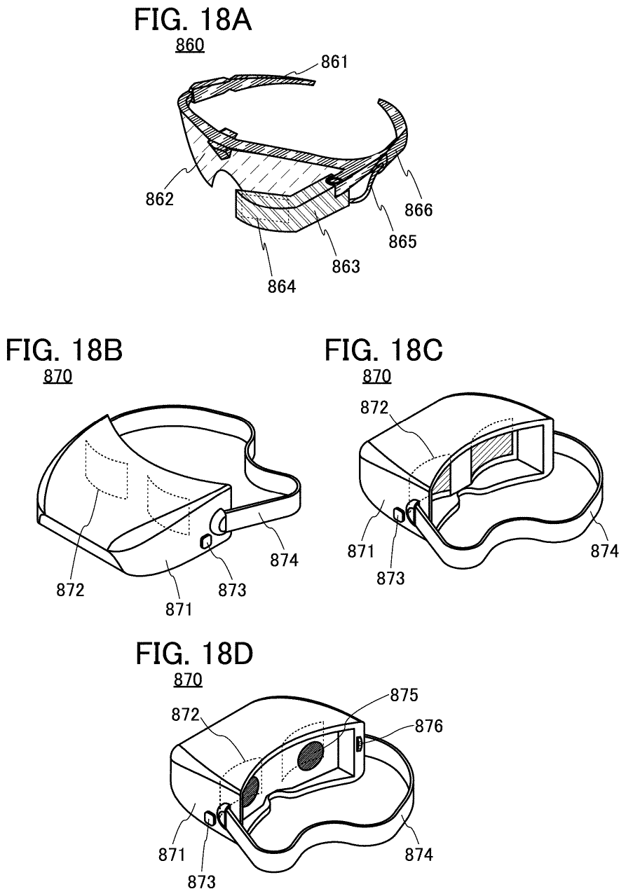

FIG. 18A shows an external view of a head-mounted display 860.

The head-mounted display 860 includes a mounting portion 861, a lens 862, a main body 863, a display portion 864, a cable 865, and the like. A battery 866 is incorporated in the mounting portion 861.

The cable 865 supplies electric power from the battery 866 to the main body 863. The main body 863 includes a wireless receiver or the like and can display received image information, such as image data, on the display portion 864. The movement of the eyeball and the eyelid of a user is captured by a camera provided in the main body 863, and the coordinates of the sight line of the user are calculated using the information to utilize the sight line of the user as an input means.

A plurality of electrodes may be provided in the mounting portion 861 at positions in contact with the user. The main body 863 may have a function of recognizing the user's sight line by sensing a current that flows through the electrodes in accordance with the movement of the user's eyeball. The main body 863 may have a function of monitoring the user's pulse by sensing a current flowing through the electrodes. The mounting portion 861 may include various sensors such as a temperature sensor, a pressure sensor, and an acceleration sensor and may have a function of displaying the user's biological information on the display portion 864. The main body 863 may sense the movement of the user's head or the like to change an image displayed on the display portion 864 in synchronization with the movement.

The display portion 864 can use the display device of one embodiment of the present invention.

FIG. 18B and FIG. 18C show external views of a head-mounted display 870.

The head-mounted display 870 includes a housing 871, two display portions 872, an operation button 873, and a fixing band 874.

The head-mounted display 870 has the functions of the above-described head-mounted display 860 and includes two display portions.

Since the head-mounted display 870 includes the two display portions 872, the user's eyes can see their respective display portions. Thus, a high-resolution image can be displayed even when a three-dimensional display using parallax or the like is performed. In addition, the display portion 872 is curved around an arc with the user's eye as an approximate center. Thus, distances between the user's eye and display surfaces of the display portion become equal; thus, the user can see a more natural image. Even when the luminance or chromaticity of light from the display portion is changed depending on the angle at which the user see it, since the user's eye is positioned in a normal direction of the display surface of the display portion, the influence of the change can be substantially ignorable and thus a more realistic image can be displayed.

The operation button 873 has a function of a power button or the like. A button other than the operation button 873 may be included.

As illustrated in FIG. 18D, lenses 875 may be provided between the display portion 872 and the user's eyes. The user can see magnified images on the display portion 872 through the lenses 875, leading to a higher realistic sensation. In that case, as illustrated in FIG. 18D, a dial 876 for changing the position of the lenses and adjusting visibility may be included.

The display portion 872 can use the display device of one embodiment of the present invention. The display device of one embodiment of the present invention has an extremely high resolution; thus, even when an image is magnified using the lenses 875 as in FIG. 18D, the user does not perceive pixels, and a more realistic image can be displayed.

Note that the shape of the display portion 872 in FIG. 18B to FIG. 18D is not limited to a shape surrounded by two sides facing each other. The shape of the display portion 872 can be selected from a variety of shapes depending on the size or structure of the housing. For example, the display portion 872 can have an elliptical shape. For example, a display device corresponding to the shape of the lens 862 illustrated in FIG. 18A may be provided.

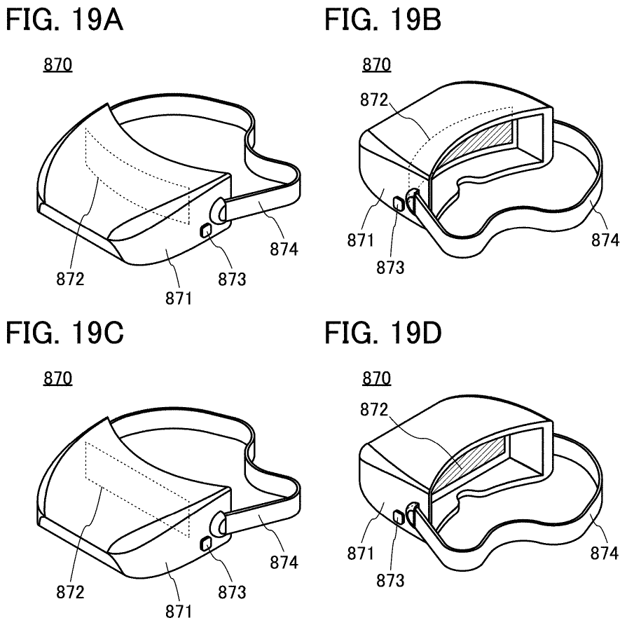

FIG. 19A and FIG. 19B show an example in which one display portion 872 is provided. This structure can reduce the number of components.

The display portion 872 can display an image for the right eye and an image for the left eye side by side on a right region and a left region, respectively. Thus, a three-dimensional image using binocular disparity can be displayed.

One image which can be seen by both eyes may be displayed on the entire display portion 872. A panorama image can thus be displayed from end to end of the field of view, which can provide a higher sense of reality.

The above-described lenses 875 may be provided. Two images may be displayed side by side on the display portion 872 or one image may be displayed on the display portion 872 and seen by both eyes through the lenses 875.

The display portion 872 is not necessarily curved, and the display surface may be flat. For example, FIG. 19C and FIG. 19D show examples of the case where one display portion 872 that does not have a curved surface is provided.

The composition, structure, method, and the like described in this embodiment can be used in an appropriate combination with the compositions, structures, methods, and the like described in the other embodiments.

### Embodiment 6

In this embodiment, application examples of the above-described display device including a display region with a free shape will be described.

### [Electronic Device]

Next, examples of electronic devices each provided with the display device of one embodiment of the present invention including a display region with a free shape will be described.

Examples of electronic devices each using the display device of one embodiment of the present invention including a display region with a free shape include display devices such as televisions, monitors, and the like; lighting devices; desktop personal computers; laptop personal computers; word processors; image reproduction devices that reproduce still images and moving images stored in recording media such as DVDs (Digital Versatile Discs); portable CD players; radios; tape recorders; headphone stereos; stereos; table clocks; wall clocks; cordless phone handsets; transmission/reception devices; mobile phones; car phones; portable game machines; tablet terminals; large-sized game machines such as pachinko machines; calculators; portable electronic devices; electronic notebooks; e-book readers; electronic translators; audio input devices; video cameras; digital still cameras; electric shavers; high-frequency heating appliances such as microwave ovens; electric rice cookers; electric washing machines; electric vacuum cleaners; water heaters; electric fans; hair dryers; air-conditioning systems such as air conditioners, humidifiers, and dehumidifiers; dishwashers; dish dryers; clothes dryers; futon dryers; electric refrigerators; electric freezers; electric refrigerator-freezers; freezers for preserving DNA; flashlights; tools such as chain saws; smoke detectors; and medical equipment such as dialyzers. Other examples include display devices included in control portions of industrial equipment such as guide lights, traffic lights, conveyor belts, elevators, escalators, industrial robots, power storage systems, and power storage devices for leveling the amount of power supply and smart grid.

In addition, the display device including a display region with a free shape can be incorporated in wearable electronic devices such as head-mounted displays, smartwatches, vital information measurement devices, helmets, clothes, displays for digital signage, and the like.

The display device including a display region with a free shape can be incorporated along a curved surface of an inside wall or an outside wall of a house or a building or the interior or the exterior of a vehicle.

In addition, moving objects and the like driven by electric motors using electric power from the power storage devices are also included in the category of electronic devices. Examples of the moving objects include electric vehicles (EVs), hybrid electric vehicles (HEVs) that include both an internal-combustion engine and a motor, plug-in hybrid electric vehicles (PHEVs), tracked vehicles in which caterpillar tracks are substituted for wheels of these vehicles, motorized bicycles including motor-assisted bicycles, motorcycles, electric wheelchairs, golf carts, boats, ships, submarines, helicopters, aircraft, rockets, artificial satellites, space probes, planetary probes, and spacecraft.

The above-described display device included in the electronic device preferably includes an antenna. When a signal is received with the antenna, an image, information, or the like can be displayed on the display portion. Thus, the display device of one embodiment of the present invention can be used for communication devices in any of the electronic devices.

The above-described display device included in the electronic device may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, electric power, radiation, flow rate, humidity, gradient, oscillation, a smell, or infrared rays), for example. The sensor is preferably a MEMS.

The electronic device can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function including 5G communication, and a function of reading out a program or data stored in a recording medium.

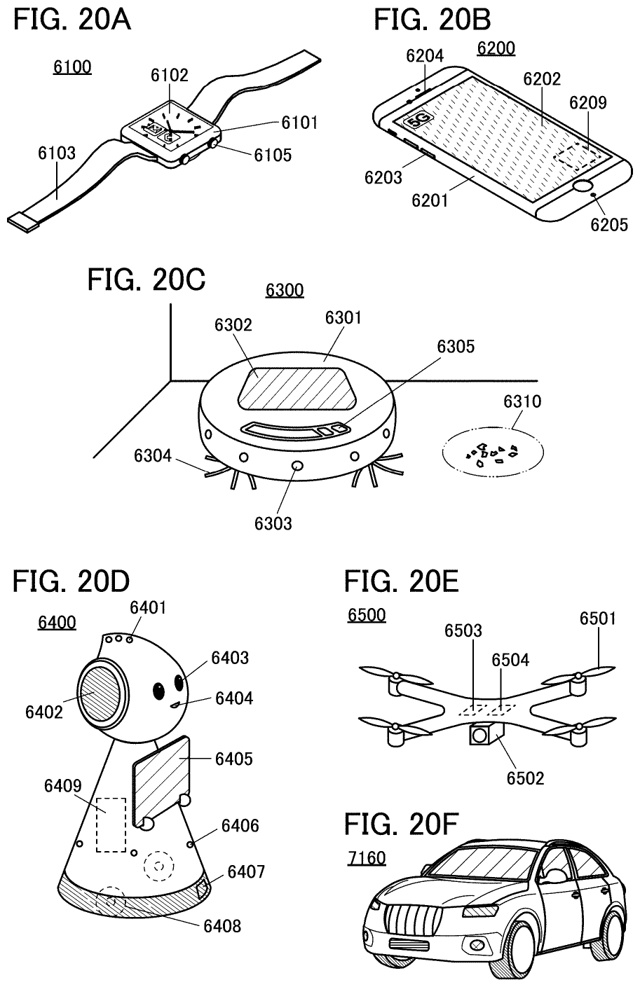

FIG. 20A to FIG. 20F show examples of electronic devices. The display device of one embodiment of the present invention can be used as a display device or a display portion of the electronic device described below.

FIG. 20A shows an example of a watch-type portable electronic device. A portable electronic device 6100 includes a housing 6101, a display portion 6102, a band 6103, operation buttons 6105, and the like. The portable electronic device 6100 further includes a secondary battery and the semiconductor device of one embodiment of the present invention or the electronic component. The portable electronic device 6100 including the semiconductor device of one embodiment of the present invention or the electronic component can function as an IoT device.

FIG. 20B shows an example of a mobile phone. A mobile phone 6200 includes a display portion 6202 incorporated in a housing 6201, operation buttons 6203, a speaker 6204, a microphone 6205, and the like.

The mobile phone 6200 further includes a fingerprint sensor 6209 in a region overlapping with the display portion 6202. The fingerprint sensor 6209 may be an organic optical sensor. Since a fingerprint differs between individuals, the fingerprint sensor 6209 can perform personal authentication when acquiring fingerprint patterns. As a light source for acquiring fingerprint patterns with the fingerprint sensor 6209, light emitted from the display portion 6202 can be used.

The mobile phone 6200 further includes a secondary battery and the semiconductor device of one embodiment of the present invention or the electronic component. The mobile phone 6200 including the semiconductor device of one embodiment of the present invention or the electronic component can function as an IoT device.

FIG. 20C shows an example of a cleaning robot. A cleaning robot 6300 includes a display portion 6302 placed on the top surface of a housing 6301, a plurality of cameras 6303 placed on the side surface of the housing 6301, a brush 6304, operation buttons 6305, a variety of sensors, and the like. Although not illustrated, a tire, an inlet, and the like are provided for the cleaning robot 6300. The cleaning robot 6300 is self-propelled, detects dust 6310, and sucks up the dust through the inlet provided on the bottom surface.

For example, the cleaning robot 6300 can determine whether there is an obstacle such as a wall, furniture, or a step by analyzing images taken by the cameras 6303. In the case where the cleaning robot 6300 detects an object that is likely to be caught in the brush 6304 (e.g., a wire) by image analysis, the rotation of the brush 6304 can be stopped. The cleaning robot 6300 includes a secondary battery and the semiconductor device of one embodiment of the present invention or the electronic component. The cleaning robot 6300 including the semiconductor device of one embodiment of the present invention or the electronic component can function as an IoT device.

FIG. 20D shows an example of a robot. A robot 6400 illustrated in FIG. 20D includes an arithmetic device 6409, an illuminance sensor 6401, a microphone 6402, an upper camera 6403, a speaker 6404, a display portion 6405, a lower camera 6406, an obstacle sensor 6407, and a moving mechanism 6408.

The microphone 6402 has a function of detecting a speaking voice of a user, an environmental sound, and the like. The speaker 6404 has a function of outputting sound. The robot 6400 can communicate with a user using the microphone 6402 and the speaker 6404.

The display portion 6405 has a function of displaying various kinds of information. The robot 6400 can display information desired by a user on the display portion 6405. The display portion 6405 may be provided with a touch panel. Moreover, the display portion 6405 may be a detachable electronic device, in which case charging and data communication can be performed when the display portion 6405 is set at the home position of the robot 6400.

The upper camera 6403 and the lower camera 6406 each have a function of taking an image of the surroundings of the robot 6400. The obstacle sensor 6407 can detect an obstacle in the direction where the robot 6400 advances with the moving mechanism 6408. The robot 6400 can move safely by recognizing the surroundings with the upper camera 6403, the lower camera 6406, and the obstacle sensor 6407. The light-emitting device of one embodiment of the present invention can be used for the display portion 6405.

The robot 6400 includes a secondary battery and the semiconductor device of one embodiment of the present invention or the electronic component. The robot 6400 including the semiconductor device of one embodiment of the present invention or the electronic component can function as an IoT device.

FIG. 20E shows an example of a flying object. A flying object 6500 illustrated in FIG. 20E includes propellers 6501, a camera 6502, a battery 6503, and the like and has a function of flying autonomously.

For example, image data taken by the camera 6502 is stored in an electronic component 6504. The electronic component 6504 can analyze the image data to detect whether there is an obstacle in the way of the movement. Moreover, the electronic component 6504 can estimate the remaining battery level from a change in the power storage capacity of the battery 6503. The flying object 6500 includes the semiconductor device of one embodiment of the present invention or the electronic component. The flying object 6500 including the semiconductor device of one embodiment of the present invention or the electronic component can function as an IoT device.

FIG. 20F shows an example of an automobile. An automobile 7160 includes an engine, tires, a brake, a steering gear, a camera, and the like. The automobile 7160 further includes the semiconductor device of one embodiment of the present invention or the electronic component. The automobile 7160 including the semiconductor device of one embodiment of the present invention or the electronic component can function as an IoT device.

The composition, structure, method, and the like described in this embodiment can be used in an appropriate combination with the compositions, structures, methods, and the like described in the other embodiments.

### REFERENCE NUMERALS

ANT1: antenna region, ANT2: antenna region, C1: capacitor, C2: capacitor, CK1: input terminal, CK2: input terminal, d1: distance, d2: distance, L1: layer, L1A: layer, L1B: layer, L2: layer, L2A: layer, L2B: layer, ND2: node, ND3: node, Pix1: pixel, Pix2: pixel, Sen1: sensor, Sen2: sensor, 10: display device, 10A: display device, 10B: display device, 10C: display device, 20: sensor, 20A: source driver, 20A1: output terminal, 20B: source driver, 20B1: output terminal, 20C: sensor, 20C1: sensor, 20C2: sensor, 20D: transmission/reception device, 20D1: transmission/reception device, 20D2: transmission/reception device, 30: timing controller, 30a: output terminal, 40: pixel, 40A: pixel, 40B: pixel, 40D: circuit, 40D1: circuit, 40D2: circuit, 41: light-emitting element, 42: transistor, 42a: transistor, 43: transistor, 44: transistor, 45: wiring, 45b: wiring, 46: wiring, 48: wiring, 48a: wiring, 48g: wiring, 49: wiring, 49a: wiring, 49b: wiring, 51a: electrode, 51b: electrode, 51c: electrode, 55a: plug, 55b: plug, 55c: plug, 55d: plug, 55e: plug, 57a: plug, 57b: plug, 57c: plug, 58: space, 59: bump, 59a: bump, 59b: bump, 59c: bump, 61a: electrode, 61b: electrode, 61c: electrode, 61d: electrode, 61e: electrode, 63a: plug, 63b: plug, 63c: plug, 72: insulating layer, 74: insulating layer, 76: insulating film, 78: insulating film, 81: transistor, 82: transistor, 83: transistor, 84: transistor, 85: transistor, 86: transistor, 87: transistor, 88: transistor, 89: transistor, 90: transistor, 91: transistor, 94: capacitor, 95: capacitor, 96: capacitor, 100: electronic device, 100A: substrate, 100B: FPC, 100C: control device, 101A: bump, 101B: bump, 110: display region, 404: insulator, 500: transistor, 500A: transistor, 500B: transistor, 503: conductor, 503a: conductor, 503b: conductor, 512: insulator, 513: insulator, 514: insulator, 516: insulator, 520: insulator, 522: insulator, 524: insulator, 530: oxide, 530a: oxide, 530b: oxide, 540a: conductor, 540b: conductor, 542: conductor, 542a: conductor, 542b: conductor, 543a: region, 543b: region, 544: insulator, 545: insulator, 550: transistor, 552: insulator, 560: conductor, 560a: conductor, 560b: conductor, 574: insulator, 580: insulator, 581: insulator, 860: head-mounted display, 861: mounting portion, 862: lens, 863: main body, 864: display portion, 865: cable, 866: battery, 870: head-mounted display, 871: housing, 872: display portion, 873: operation button, 874: fixing band, 875: lens, 876: dial, 900: wireless transmission/reception device, 900A: wireless transmission/reception device, 901: low-noise amplifier, 902: band pass filter, 903: mixer, 904: band pass filter, 905: demodulator, 906: decoder circuit, 911: power amplifier, 912: band pass filter, 913: mixer, 914: band pass filter, 915: modulator, 916: decoder circuit, 921: duplexer, 922: local oscillator, 931: antenna, 941: signal, 942: signal, 943: signal, 944: signal, 6100: portable electronic device, 6101: housing, 6102: display portion, 6103: band, 6105: operation button, 6200: mobile phone, 6201: housing, 6202: display portion, 6203: operation button, 6204: speaker, 6205: microphone, 6209: fingerprint sensor, 6300: cleaning robot, 6301: housing, 6302: display portion, 6303: camera, 6304: brush, 6305: operation button, 6310: dust, 6400: robot, 6401: illuminance sensor, 6402: microphone, 6403: upper camera, 6404: speaker, 6405: display portion, 6406: lower camera, 6407: obstacle sensor, 6408: moving mechanism, 6409: arithmetic device, 6500: flying object, 6501: propeller, 6502: camera, 6503: battery, 6504: electronic component, 7160: automobile

1. A display device comprising a first layer and a second layer,
wherein the first layer comprises a source driver and a first component of a sensor,
wherein the second layer comprises a gate driver, a plurality of pixels, and a second component of the sensor,
wherein an opening portion and a first terminal are provided in the first layer,
wherein the first component of the sensor is provided in the opening portion,
wherein the first terminal is electrically connected to the source driver,
wherein the pixels are provided on a first surface of the second layer,
wherein a second terminal is provided on a second surface of the second layer which is opposite to the first surface,
wherein the second terminal is electrically connected to the pixels, and
wherein the first terminal is electrically connected to the second terminal.

2. The display device according to claim 1,
wherein the sensor functions as MEMS.

3. A display device comprising a first layer and a second layer,
wherein the first layer comprises a source driver,
wherein the second layer comprises a gate driver, a plurality of pixels, and an antenna,
wherein one or both of the gate driver and the pixels are formed in a position overlapping with the antenna,
wherein the first layer comprises a first terminal and a third terminal,
wherein the first terminal is electrically connected to the source driver,
wherein the pixels are provided on a first surface of the second layer,
wherein a second terminal is provided on a second surface of the second layer which is opposite to the first surface,
wherein the second terminal is electrically connected to the pixels,
wherein the first terminal is electrically connected to the second terminal, and
wherein the third terminal is electrically connected to an end portion of the antenna.

4. The display device according to claim 1,
wherein the second layer has a larger area than the first layer, and the second layer comprises a region overlapping with the first layer.

5. The display device according to claim 1,
wherein a first pixel and a second pixel are included as the pixels,
wherein the first pixel and the second pixel each comprise a light-emitting element, and
wherein the second pixel further comprises a component of the gate driver.

6. The display device according to claim 1,
wherein the first terminal and the second terminal are provided in a position overlapping with a wiring to which the plurality of pixels are connected.

7. The display device according to claim 1,
wherein the first terminal is electrically connected to the second terminal through a bump.

8. The display device according to claim 5,
wherein the light-emitting element comprises an organic substance.

9. A display device comprising a first layer and a second layer,
wherein the first layer comprises a first transistor and a first component of a sensor,
wherein the second layer comprises a second transistor, a light-emitting element, and a second component of the sensor,
wherein the sensor is provided in a region overlapping with the first transistor,
wherein an opening portion and a first terminal are provided in the first layer,
wherein the first component of the sensor is provided in the opening portion,
wherein the first terminal is electrically connected to the first transistor,
wherein the light-emitting element is provided on a first surface of the second layer,
wherein a second terminal of the second transistor is provided on a second surface of the second layer which is opposite to the first surface, and
wherein the first terminal is electrically connected to the second terminal.

10. The display device according to claim 9,
wherein the second transistor comprises a metal oxide in a semiconductor layer.

11. The display device according to claim 9,
wherein the second transistor comprising a metal oxide in the semiconductor layer comprises a back gate.

12. The display device according to claim 3,
wherein the second layer has a larger area than the first layer, and the second layer comprises a region overlapping with the first layer.

13. The display device according to claim 3,
wherein a first pixel and a second pixel are included as the pixels,
wherein the first pixel and the second pixel each comprise a light-emitting element, and
wherein the second pixel further comprises a component of the gate driver.

14. The display device according to claim 3,
wherein the first terminal and the second terminal are provided in a position overlapping with a wiring to which the plurality of pixels are connected.

15. The display device according to claim 3,
wherein the first terminal is electrically connected to the second terminal through a bump.

16. The display device according to claim 3,
wherein the light-emitting element comprises an organic substance.
